(19) United States
(12) Patent Application Publication
(10) Pub. No.: US 2015/0109019 A1
(43) Pub. Date: Apr. 23, 2015

(54) METHOD FOR EVALUATING SEMICONDUCTOR DEVICE

(71) Applicant: Semiconductor Energy Laboratory Co., Ltd., Atsugi-shi (JP)

(72) Inventors: Shinpei MATSUDA, Atsugi (JP); Toshihiko TAKEUCHI, Atsugi (JP); Daisuke MATSUBAYASHI, Ebina (JP)

(73) Assignee: Semiconductor Energy Laboratory Co., Ltd.

(21) Appl. No.: 14/516,096

(22) Filed: Oct. 16, 2014

(30) Foreign Application Priority Data
Oct. 22, 2013 (JP) 2013-219017

(51) Int. Cl. G01R 31/26; G01R 27/26

(52) U.S. Cl. CPC G01R 31/2601; G01R 27/2605
USPC 324/762.01

(57) ABSTRACT

A method for evaluating a buried channel in a semiconductor device including a semiconductor layer having a stacked-layer structure is provided. A method for evaluating a semiconductor device is provided, which includes the steps of: electrically short-circuiting a source and a drain of a transistor; applying DC voltage and AC voltage to a gate to obtain a CV characteristic that indicates a relationship between the DC voltage and a capacitance between the gate and each of the source and the drain; and determining that a semiconductor layer of the transistor includes a stacked-layer structure, when the capacitance in a region in an accumulation state in the CV characteristic is increased stepwise.

### BACKGROUND OF THE INVENTION

1. Field of the Invention

The present invention relates to an object, a method, or a manufacturing method. In addition, the present invention relates to a process, a machine, manufacture, or a composition of matter. One embodiment of the present invention particularly relates to a semiconductor device and a method for evaluating the semiconductor device.

In this specification and the like, a semiconductor device generally means a device that can function by utilizing semiconductor characteristics. An electro-optical device, an image display device (also simply referred to as a display device), a semiconductor circuit, a light-emitting device, a power storage device, a memory device, and an electronic appliance may include a semiconductor device.

2. Description of the Related Art

A transistor formed using a semiconductor is applied to a wide range of electronic devices such as integrated circuits (ICs) and image display devices. To improve the electrical characteristics and/or the reliability of a transistor, what is called a buried channel structure has been considered in which a second semiconductor layer is provided between a first semiconductor layer where a channel is formed and a gate insulating layer so that the gate insulating layer is apart from the channel (e.g., Patent Documents 1 and 2).

### REFERENCE

### Patent Documents

[Patent Document 1] Japanese Published Patent Application No. 2011-124360
[Patent Document 2] Japanese Published Patent Application No. 2013-038401

### SUMMARY OF THE INVENTION

In order that a region where a channel is formed is apart from a gate insulating layer, there is a method in which a first semiconductor layer functioning as a channel is formed using a semiconductor layer which has lower energy of the bottom of the conduction band than a second semiconductor layer in contact with the first semiconductor layer, so that a conduction band offset is formed between the two layers. In general, to measure the energy of the bottom of the conduction band, an evaluation method that is not simple, such as ultraviolet photoemission spectroscopy or X-ray photoelectron spectroscopy, needs to be applied. Therefore, it is difficult to determine whether a buried channel is formed in a stacked-layer structure or to select conditions for forming the buried channel.

Thus, an object of one embodiment of the present invention is to provide a new method for evaluating a semiconductor device including a semiconductor layer having a stacked-layer structure.

Another object of one embodiment of the present invention is to provide a method for evaluating optimal conditions of a semiconductor device in such a manner that a plurality of semiconductor devices having different conditions (e.g., thicknesses or compositions) is measured and the obtained results are compared with each other.

Another object of one embodiment of the present invention is to improve the reliability of a semiconductor device. Another object of one embodiment of the present invention is to provide a method for manufacturing a semiconductor device, which enables improvement of reliability.

Another object of one embodiment of the present invention is to improve electrical characteristics of a semiconductor device. Another object of one embodiment of the present invention is to provide a method for manufacturing a semiconductor device, which enables improvement of electrical characteristics. Another object of one embodiment of the present invention is to provide a new method for manufacturing a semiconductor device. Another object of one embodiment of the present invention is to provide a new method for measuring a semiconductor device.

Note that the description of these objects does not disturb the description of other objects. One embodiment of the present invention does not necessarily achieve all the objects. Objects other than the above objects will be apparent from and can be derived from the description of the specification and the like.

One embodiment of the present invention is a method for evaluating a semiconductor device, including the steps of electrically short-circuiting a source and a drain of a transistor; applying DC voltage and AC voltage to a gate to obtain a CV characteristic that indicates a relationship between the DC voltage and a capacitance between the gate and each of the source and the drain; and determining that a semiconductor layer of the transistor includes a stacked-layer structure, when the capacitance in a region in an accumulation state in the CV characteristic is increased stepwise.

Another embodiment of the present invention is a method for evaluating a semiconductor device, including the steps of: using a transistor including a stacked-layer structure including a first semiconductor layer and a second semiconductor layer that is closer to a gate than the first semiconductor layer; electrically short-circuiting a source and a drain of the transistor; applying DC voltage and AC voltage to the gate to obtain a CV characteristic that indicates a relationship between the DC voltage and a capacitance between the gate and each of the source and the drain; and determining that a channel of the transistor is formed in the first semiconductor layer with an application voltage that is lower than or equal to the DC voltage at which the capacitance has a first saturated value, when the capacitance in a region in an accumulation state in the CV characteristics has the first saturated value and a capacitance value higher than the first saturated value.

Another embodiment of the present invention is a method for evaluating a semiconductor device, including the steps of: using a first transistor including a stacked-layer structure of a first semiconductor layer and a second semiconductor layer, a first source, a first drain, and a first gate; and a second transistor including a stacked-layer structure of a third semiconductor layer and a fourth semiconductor layer, a second source, a second drain, and a second gate; electrically short-circuiting the first source and the first drain; applying DC voltage and AC voltage to the first gate to obtain a first CV characteristic that indicates a relationship between the DC voltage applied to the first gate and a capacitance between the first gate and each of the first source and the first drain; electrically short-circuiting the second source and the second drain; applying DC voltage and AC voltage to the second gate to obtain a second CV characteristic that indicates a relationship between the DC voltage applied to the second gate and a capacitance between the second gate and each of the second source and the second drain; and evaluating an optimal composition from the second semiconductor layer and the fourth semiconductor layer by comparison between the first CV characteristic and the second CV characteristic. In the embodiment, the first semiconductor layer and the third semiconductor layer have the same composition and the same thickness, and the second semiconductor layer and the fourth semiconductor layer have different compositions and the same thickness.

Another embodiment of the present invention is a method for evaluating a semiconductor device, including the steps of: using a first transistor including a stacked-layer structure of a first semiconductor layer and a second semiconductor layer, a first source, a first drain, and a first gate; and a second transistor including a stacked-layer structure of a third semiconductor layer and a fourth semiconductor layer, a second source, a second drain, and a second gate; electrically short-circuiting the first source and the first drain; applying DC voltage and AC voltage to the first gate to obtain a first CV characteristic that indicates a relationship between the DC voltage applied to the first gate and a capacitance between the first gate and each of the first source and the first drain; electrically short-circuiting the second source and the second drain; applying DC voltage and AC voltage to the second gate to obtain a second CV characteristic that indicates a relationship between the DC voltage applied to the second gate and a capacitance between the second gate and each of the second source and the second drain; and evaluating an optimal thickness from the second semiconductor layer and the fourth semiconductor layer by comparison between the first CV characteristic and the second CV characteristic. In the embodiment, the first semiconductor layer and the third semiconductor layer have the same composition and the same thickness, and the second semiconductor layer and the fourth semiconductor layer have the same composition and different thicknesses.

Another embodiment of the present is a method for evaluating a semiconductor device, including the steps of: using a first transistor including a stacked-layer structure of a first semiconductor layer and a second semiconductor layer, a first source, a first drain, a first gate, and a first gate insulating layer; and a second transistor including a stacked-layer structure of a third semiconductor layer and a fourth semiconductor layer, a second source, a second drain, a second gate, and a second gate insulating layer; electrically short-circuiting the first source and the first drain; applying DC voltage and AC voltage to the first gate to obtain a first CV characteristic that indicates a relationship between the DC voltage applied to the first gate and a capacitance between the first gate and each of the first source and the first drain; electrically short-circuiting the second source and the second drain; applying DC voltage and AC voltage to the second gate to obtain a second CV characteristic that indicates a relationship between the DC voltage applied to the second gate and a capacitance between the second gate and each of the second source and the second drain; and evaluating an optimal thickness from the first gate insulating layer and the second gate insulating layer by comparison between the first CV characteristic and the second CV characteristic. In the embodiment, the first semiconductor layer and the third semiconductor layer have the same composition and the same thickness, the second semiconductor layer and the fourth semiconductor layer have the same composition and the same thickness, and the first gate insulating layer and the second gate insulating layer have the same composition and different thicknesses.

According to one embodiment of the present invention, a new method for evaluating a semiconductor device including a semiconductor layer having a stacked-layer structure can be provided. According to one embodiment of the present invention, an optimal condition in each of a plurality of semiconductor devices having different conditions can be evaluated.

According to one embodiment of the present invention, the reliability of a semiconductor device can be improved. According to one embodiment of the present invention, a method for manufacturing a semiconductor device with improved reliability can be provided.

According to one embodiment of the present invention, the electrical characteristics of a semiconductor device can be improved. According to one embodiment of the present invention, a method for manufacturing a semiconductor device with improved electrical characteristics can be provided.

Note that the description of these effects does not disturb the existence of other effects. One embodiment of the present invention does not necessarily achieve all the objects listed above. Other effects will be apparent from and can be derived from the description of the specification, the drawings, the claims, and the like.

### BRIEF DESCRIPTION OF THE DRAWINGS

FIG. 1 is a cross-sectional view illustrating a semiconductor device of one embodiment of the present invention.

FIG. 2 is a model diagram showing an example of CV characteristics. FIGS. 3A1 and 3A2 and FIGS. 3B1 and 3B2 are top views and cross-sectional views illustrating a semiconductor device of one embodiment of the present invention and a semiconductor device of a comparative example.

FIGS. 4A and 4B show measurement results of CV characteristics.

FIG. 5 illustrates the structure of a semiconductor device used for calculation.

FIG. 6 shows calculation results of CV characteristics.

FIG. 7 shows measured CV characteristics and calculation results of CV characteristics.

FIGS. 8A to 8D show calculation results of CV characteristics.

FIGS. 9A and 9B show calculation results of band diagrams.

FIGS. 10A to 10C are a plan view and cross-sectional views illustrating a semiconductor device of one embodiment of the present invention.

FIGS. 11A and 11B are a plan view and a cross-sectional view illustrating semiconductor device of one embodiment of the present invention.

FIGS. 12A and 12B are a plan view and a cross-sectional view illustrating a semiconductor device of one embodiment of the present invention.

FIGS. 13A and 13B are circuit diagrams each illustrating a semiconductor device of one embodiment of the present invention.

FIGS. 14A to 14C are circuit diagrams and a schematic diagram of a semiconductor device of one embodiment of the present invention.

FIGS. 15A to 15C illustrate a structure of a display panel of one embodiment.

FIG. 16 is a block diagram of an electronic appliance of one embodiment.

FIGS. 17A to 17D are each an external view of an electronic appliance of one embodiment of the present invention.

### DETAILED DESCRIPTION OF THE INVENTION

Embodiments of the present invention will be described below in detail with reference to the drawings. Note that the present invention is not limited to the following description, and it is easily understood by those skilled in the art that the mode and details can be variously changed without departing from the spirit and scope of the present invention. Therefore, the present invention should not be interpreted as being limited to the description of embodiments below. In addition, in the following embodiments, the same portions or portions having similar functions are denoted by the same reference numerals or the same hatching patterns in different drawings, and description thereof will not be repeated.

Note that in each drawing described in this specification, the size, the film thickness, or the region of each component may be exaggerated for clarity. Therefore, embodiments of the present invention are not limited to such a scale.

In this specification and the like, ordinal numbers such as “first”, “second”, and the like are used in order to avoid confusion among components, and the terms do not limit the components numerically. Therefore, for example, description can be made even when “first” is replaced with “second” or “third”, as appropriate.

Functions of a “source” and a “drain” are sometimes interchanged with each other as appropriate when the direction of current flow is changed in circuit operation, for example. Thus, in this specification and the like, the terms “source” and “drain” can be replaced with each other.

The term such as “over” or “below” in this specification and the like does not necessarily mean that a component is placed “directly on” or “directly under” another component. For example, the expression “a gate electrode layer over a gate insulating layer” does not exclude the case where a component is placed between the gate insulating layer and the gate electrode layer. The same applies to the term “below”.

In this specification and the like, the term “the same” is used not only in the case where objects completely correspond to each other but also in the case where there is an error due to manufacturing variation, and thus can be used for objects that are substantially the same. For example, a difference in thickness or composition between films that are formed in the same process is an allowable error.

### Embodiment 1

In this embodiment, a method for evaluating whether a buried channel is formed or not and a method for evaluating the strength of embeddability (resistance of the buried channel against high application voltage) using results of CV measurement (CV characteristics) of a transistor including a semiconductor layer having a stacked-layer structure are described.

### <Structure Example of Semiconductor Device Used for Evaluation>

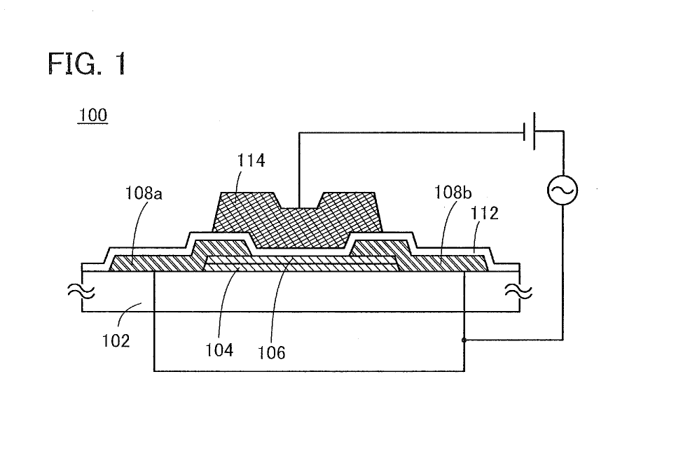

FIG. 1 illustrates the structure of a semiconductor device that is applicable to an evaluation method described in this embodiment.

FIG. 1 is a cross-sectional view illustrating a transistor 100 having a top-gate structure as an example of the semiconductor device. The transistor 100 includes a first semiconductor layer 104 and a second semiconductor layer 106 that are provided over a substrate 102, a pair of conductive layers 108a and 108b that is electrically connected to the first semiconductor layer 104 and the second semiconductor layer 106, a gate insulating layer 112 that is provided over the pair of conductive layers 108a and 108b, and a conductive layer 114 that is in contact with the gate insulating layer 112.

The pair of conductive layers 108a and 108b includes regions functioning as a source and a drain of the transistor 100. The conductive layer 114 includes a region functioning as a gate of the transistor 100.

There is no particular limitation on a material which can be used for the transistor 100, and a material which can be used for a semiconductor device can be used as appropriate.

The evaluation method described in this embodiment is the one in which CV characteristics of a transistor are obtained and whether a buried channel is formed or not is determined directly from a graph of the CV characteristics. To measure the CV characteristics of the transistor 100, the source and the drain of the transistor 100 are electrically short-circuited (i.e., the conductive layer 108a and the conductive layer 108b are electrically connected to each other), DC voltage and AC voltage are applied to the gate, and capacitance between the gate and each of the source and the drain (i.e., capacitance between the conductive layer 114 and each of the conductive layers 108a and 108b) is measured. Then, a relationship between the applied DC voltage (gate voltage) (V) and the capacitance (C) is plotted to obtain the CV characteristics of the transistor 100.

Although the transistor having a stacked-layer structure of the first and second oxide semiconductor layers is illustrated in FIG. 1 as an example of the semiconductor device used for evaluation, one embodiment of the present invention is not limited thereto. To form a buried channel, a stacked-layer structure of at least two semiconductor layers needs to be included, and for example, a stacked-layer structure including three or more semiconductor layers may be employed.

Although the top-gate transistor is illustrated in FIG. 1, the structure of a semiconductor device applicable to one embodiment of the present invention is not limited thereto, and a bottom-gate transistor, a dual-gate transistor, or the like may be alternatively applied.

### <Method for Evaluating Semiconductor Device Using CV Characteristics>

Next, a method for evaluating whether a buried channel is formed or not using the CV characteristics of a transistor having a stacked-layer structure is described.

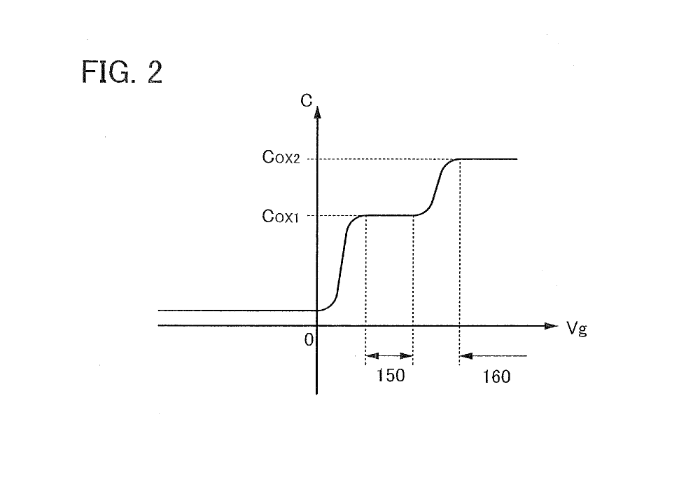

FIG. 2 is a schematic diagram showing the CV characteristics of the transistor including the semiconductor layer having a stacked-layer structure in FIG. 1 in the case where a buried channel is formed. Note that FIG. 2 shows the case where the first semiconductor layer 104 and the second semiconductor layer 106 each have an oxide semiconductor layer.

In the transistor 100, electrons respond to AC voltage on the first semiconductor layer 104 side of the interface between the second semiconductor layer 106 and the first semiconductor layer 104, in a first region 150. That is, the channel is embedded in the first semiconductor layer 104, a capacitance value C is saturated at a combined capacitance C_{OX1} of the gate insulating layer 112 and the second semiconductor layer 106.

When the application voltage is further increased while the capacitance value C is kept saturated at the combined capacitance C_{OX1} of the gate insulating layer 112 and the second semiconductor layer 106, embedment is broken and electrons existing at and in the vicinity of the interface between the second semiconductor layer 106 and the gate insulating layer 112 respond to the AC voltage. In other words, electrons can also be accumulated in the second semiconductor layer, and thus the capacitance value C is increased again. Then, the capacitance value C is saturated at a capacitance C_{OX2} of the gate insulating layer 112 in a second region 160.

Accordingly, in the case where a buried channel is formed in the transistor 100, the CV characteristics show that the capacitance value C in a region in an accumulation state is saturated at a certain value, and is then increased again by an increase in application voltage. That is, in the CV characteristics of the transistor including the semiconductor layer having a stacked-layer structure, in the case where a channel is buried therein, the capacitance value C in the region in the accumulation state is increased stepwise (in two steps in FIG. 2).

Note that this tendency becomes conspicuous when the measurement frequency of the AC voltage is, for example, lower than or equal to 10 kHz, preferably lower than 10 kHz, further preferably higher than or equal to 0.3 kHz and lower than or equal to 1 kHz.

It is found from the above description that the following evaluation can be performed by obtaining the CV characteristics of the transistor:

(1) in the case where the capacitance value in the region in the accumulation state of the CV characteristics is increased stepwise, the transistor includes a semiconductor layer having a stacked-layer structure and a buried channel is formed therein;

(2) In the case where the capacitance value in the region in an accumulation state of the CV characteristics is increased stepwise, embedment of the channel in the first semiconductor layer 104 is broken at the gate voltage that begins to increase from a first saturation capacitance value corresponding the combined capacitance C_{OX1} of the gate insulating layer 112 and the second semiconductor layer 106 (the gate voltage that rises at the second step in the CV characteristics curve). That is, when the voltage applied to the gate is lower than the voltage, the channel can be embedded in the first semiconductor layer 104.

### <Verification by Measurement>

Next, a method for evaluating whether a buried channel is formed or not using the CV characteristics of the transistor having a stacked-layer structure is described using a specific example. Furthermore, the CV characteristics of a transistor having a single-layer structure is described as a comparative example.

FIGS. 3A1 and 3A2, illustrate the structure of a transistor 200 including a semiconductor layer having a stacked-layer structure, which is used for measuring CV characteristics in this embodiment. FIG. 3A2 is a cross-sectional view taken along line X1-Y1 in FIG. 3A1. FIGS. 3B1 and 3B2 illustrate the structure of a transistor 300 including a semiconductor layer having a single layer structure, which is used for measuring CV characteristics of a comparative example. Note that FIG. 3B2 is a cross-sectional view taken along line X2-Y2 in FIG. 3B1.

### <<Method for Manufacturing Transistor 200>>

The transistor 200 includes, over a substrate 202, a base insulating layer 203; a first oxide semiconductor layer 204 and a second oxide semiconductor layer 206; a pair of conductive layers 208a and 208b electrically connected to the first oxide semiconductor layer 204 and the second oxide semiconductor layer 206; a third oxide semiconductor layer 210 in contact with the second oxide semiconductor layer 206 in a region between the pair of conductive layers 208a and 208b; a gate insulating layer 212 in contact with the third oxide semiconductor layer 210; and a conductive layer 214 in contact with the gate insulating layer 212. The transistor 200 may further include the following components: an insulating layer 216, an insulating layer 218, and/or a pair of conductive layers 220a and 220b which are/is provided over the conductive layer 214.

A silicon wafer was used as the substrate 202. First of all, a 100-nm-thick thermal oxide film was formed by performing heat, treatment on the silicon wafer in an oxidizing atmosphere to which hydrogen chloride was added. The heat treatment temperature was 950° C.

Then, as the base insulating layer 203, a 300-nm-thick silicon oxynitride film was formed over the thermal oxide film by a CVD method.

Furthermore, a surface of the silicon oxynitride film was polished to be flat by chemical mechanical polishing (CMP) treatment. The CMP treatment conditions were as follows: a polyurethane-based polishing cloth was used as a polishing pad for CMP; a 5-fold dilution of NP8020 (produced by Nitta Haas Incorporated) was used as slurry; the slurry temperature was room temperature; the polishing pressure was 0.01 MPa; the number of spindle rotations on the side where the substrate was fixed was 60 rpm; and the number of rotations of a table where the polishing cloth was fixed was 56 rpm. The CMP treatment time was 2 minutes. The polishing amount of the silicon oxynitride film was approximately 12 nm.

Next, heat treatment was performed at 450° C. in a reduced (vacuum) atmosphere for one hour.

After the heat treatment, oxygen ions were implanted to the base insulating layer 203 by an ion implantation method. The oxygen ion implantation conditions were as follows: acceleration voltage, 60 kV; dosage, 2.0×10¹⁶ ions/cm²; tilt angle, 7°; and twist angle, 72°.

Next, as the first oxide semiconductor layer 204, a 20-nm-thick In—Ga—Zn oxide semiconductor layer was formed over the base insulating layer 203 by a sputtering method using a target having an atomic ratio of In:Ga:Zn=1:3:2. Deposition conditions were as follows: the atmosphere was argon and oxygen (argon:oxygen=30 sccm:15 sccm); the pressure was 0.4 Pa; the electric power (DC) was 0.5 kW; the substrate temperature was 200° C.; and the distance between the substrate and the target was 60 mm.

After the first oxide semiconductor layer 204 was formed, the second oxide semiconductor layer 206 was successively formed without exposure to the air. As the second oxide semiconductor layer 206, a 15-nm-thick In—Ga—Zn oxide semiconductor layer was formed by a sputtering method using a target having an atomic ratio of In:Ga:Zn=1:1:1. Deposition conditions were as follows: the atmosphere was argon and oxygen (argon:oxygen=30 sccm:15 sccm); the pressure was 0.4 Pa; the electric power (DC) was 0.5 kW; the substrate temperature was 300° C.; and the distance between the substrate and the target was 60 mm.

Next, heat treatment was performed at 450° C. for one hour in a nitrogen atmosphere, and then heat treatment was performed at 450° C. for one hour in an oxygen atmosphere in the same treatment chamber.

After the heat treatment, the first oxide semiconductor layer 204 and the second oxide semiconductor layer 206 were processed into an island shape using a mask formed through a photolithography process.

A 100-nm-thick tungsten film was formed over the island shaped first oxide semiconductor layer 204 and the island-shaped second oxide semiconductor layer 206. The deposition conditions of the tungsten film were as follows: the atmosphere was argon (flow rate: 80 sccm); the pressure was 0.8 Pa; the electric power (DC) was 1 kW; the distance between the substrate and the target was 60 mm; and the substrate temperature was 130° C.

Then, the tungsten film was selectively etched to form the pair of conductive layers 208a and 208b.

As the third oxide semiconductor layer 210, a 5-nm-thick In—Ga—Zn oxide semiconductor layer was formed over the pair of conductive layers 208a and 208b by a sputtering method using an oxide target having an atomic ratio of In:Ga:Zn=1:3:2. Deposition conditions were as follows: the atmosphere was argon and oxygen (argon:oxygen=30 sccm:15 sccm); the pressure was 0.4 Pa; the electric power (DC) was 0.5 kW; the substrate temperature was 200° C.; and the distance between the substrate and the target was 60 mm.

Then, as the gate insulating layer 212, a 20-nm-thick silicon oxynitride film was deposited over the third oxide semiconductor layer 210 by a CVD method. The deposition temperature was 350° C. and the pressure was 200 Pa,

A 30-nm-thick tantalum nitride film and a 135-nm-thick tungsten film were stacked over the gate insulating layer 212 by a sputtering method, and then etched to form the conductive layer 214 including a region functioning as a gate electrode layer. The deposition conditions of the tantalum nitride film were as follows: the atmosphere was argon and nitrogen (Ar:N₂=50 sccm:10 sccm); the pressure was 0.6 Pa; the electric power was 1 kW (DC); and the distance between the substrate and the target was 60 mm. The deposition conditions of the tungsten film were as follows: the atmosphere was argon (flow rate: 100 sccm); the pressure was 2.0 Pa; the electric power was 4 kW (DC); the distance between the substrate and the target was 60 mm; and the substrate temperature was 130° C.

After a resist mask used for processing the conductive layer 214 was removed, the gate insulating layer 212 and the third oxide semiconductor layer 210 were etched using the conductive layer 214 as a mask.

Next, a 70-nm-thick aluminum oxide layer was formed as the insulating layer 216 over the conductive layer 214 to cover side surfaces of the gate insulating layer 212 and the third oxide semiconductor layer 210. The aluminum oxide layer was deposited by a sputtering method using an aluminum oxide target, and the deposition conditions were as follows: the atmosphere was argon and oxygen (argon:oxygen=25 sccm:25 sccm); the pressure was 0.4 Pa; the electric power (RF) was 2.5 kW; the substrate temperature was 250° C.; and the distance between the substrate and the target was 60 mm.

As the insulating layer 218, a 300-nm-thick silicon oxynitride film was deposited over the insulating layer 216 by a CVD method.

After that, heat treatment was performed at 400° C. for one hour in an oxygen atmosphere.

Then, contact holes reaching the pair of conductive layers 208a and 208b were formed in the insulating layer 216 and the insulating layer 218, and a conductive film to be the conductive layers 220a and 220b was formed in the contact holes and over the insulating layer 218 by a sputtering method. The conductive film had a structure in which a 50-nm-thick titanium film, a 200-nm-thick aluminum film, and a 50-nm-thick titanium film were stacked.

The deposition conditions of the titanium film were as follows: the atmosphere was argon (flow rate: 20 sccm); the pressure was 0.1 Pa; the electric power (DC) was 12 kW; the substrate temperature was room temperature; and the distance between the substrate and the target was 400 mm. Furthermore, the deposition conditions of the aluminum film were as follows: the atmosphere was argon (flow rate: 50 sccm); the pressure was 0.4 Pa; the electric power (DC) was 1 kW; the substrate temperature was room temperature; and the distance between the substrate and the target was 60 mm.

After that the stack including the conductive layers was etched to form conductive layers 220a and 220b electrically connected to the pair of conductive layers 208a and 208b, respectively.

After that, heat treatment was performed at 300° C. for one hour in an atmospheric atmosphere.

Through the above process, the transistor 200 was manufactured.

### <<Method for Manufacturing Transistor 300>>

The transistor 300 includes, over the substrate 202, a first oxide semiconductor layer 304; the pair of conductive layers 208a and 208b electrically connected to the first oxide semiconductor layer 304; the gate insulating layer 212 in contact with the first oxide semiconductor layer 304 in a region between the pair of conductive layers 208a and 208b; and the conductive layer 214 in contact with the gate insulating layer 212. The transistor 300 may further include the insulating layer 216, the insulating layer 218, and/or the pair of conductive layers 220a and 220b which are/is provided over the conductive layer 214.

In the transistor 300, a 30-nm-thick In—Ga—Zn oxide semiconductor layer was formed as the first oxide semiconductor layer 304 over the base insulating layer 203 by a sputtering method using a target having an atomic ratio of In:Ga:Zn=1:1:1. Deposition conditions were as follows: the atmosphere was argon and oxygen (argon:oxygen=30 sccm:15 sccm); the pressure was 0.4 Pa; the electric power (DC) was 0.5 kW; the substrate temperature was 300° C.; and the distance between the substrate and the target was 60 mm.

The other structures are the same as those of the transistor 200.

### <<Measurement of CV Characteristics>>

In each of the transistor 200 and the transistor 300, the source and the drain were short-circuited, DC voltage and AC voltage were applied to the gate, and a capacitance between the gate and each of the source and the drain was measured. Note that the frequency of the AC voltage applied to the gate was 1 kHz, 10 kHz, 100 kHz, or 1 MHz.

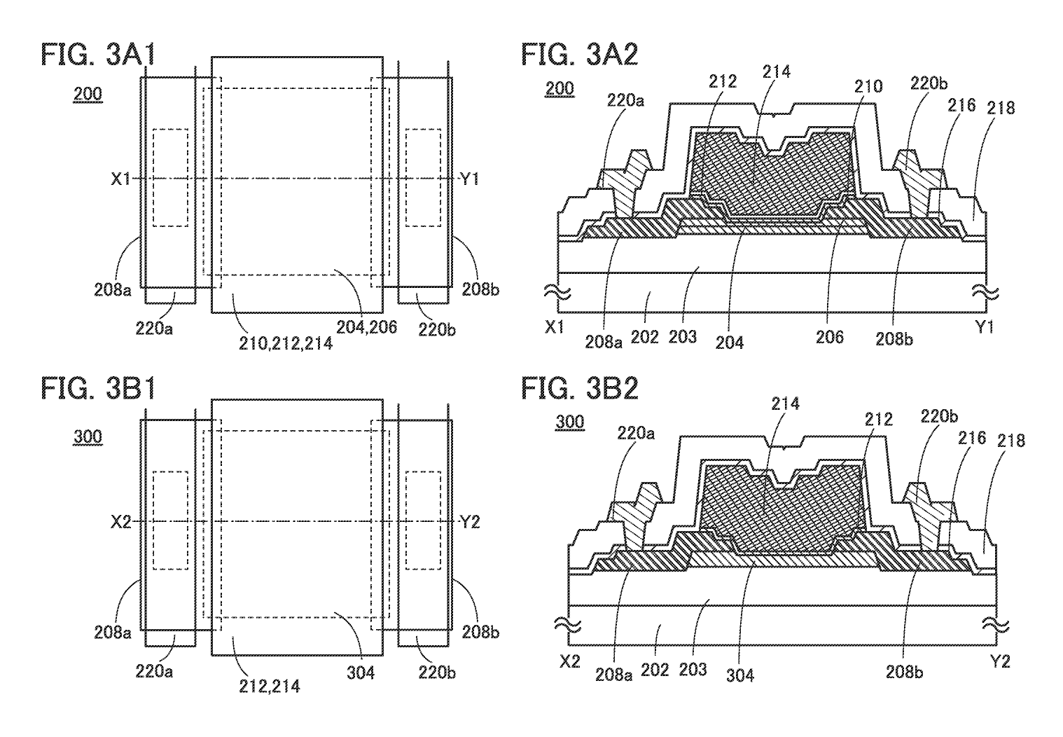

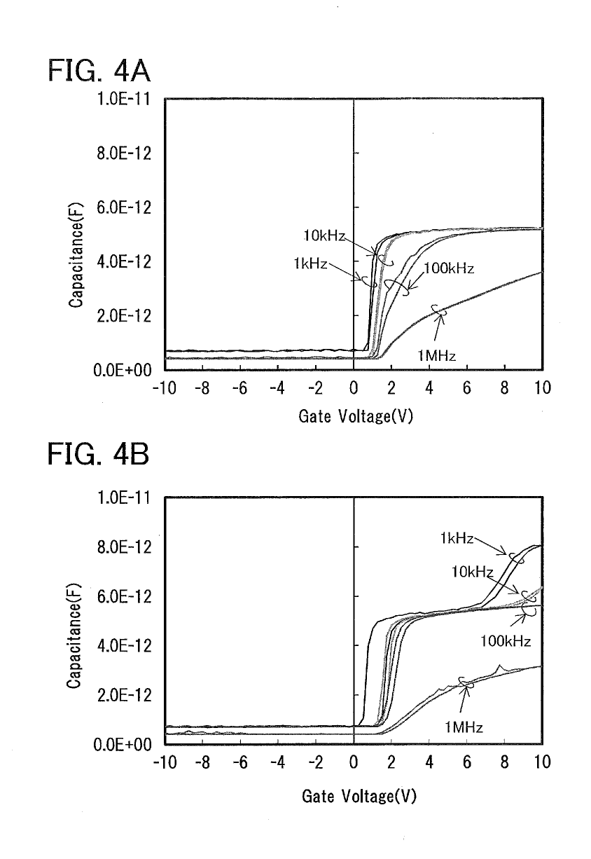

FIGS. 4A and 4B show CV characteristics indicating the relationship between the measured capacitance and the gate voltage. The CV characteristics of FIGS. 4A and 4B were obtained in such a manner that the gate voltage was swept from −10 V to +10 V, and then swept again to −10 V. FIG. 4A shows measurement results of the CV characteristics of the transistor 300 including the oxide semiconductor layer having a single-layer structure. FIG. 4B shows measurement results of the CV characteristics of the transistor 200 including the oxide semiconductor layer having a stacked-layer structure.

Note that the transistors used for the measurement each had a channel length L of 50 μm, a channel width W of 50 μm, and Lov of 3 μm.

FIG. 4A shows that the capacitance value in a region in an accumulation state is saturated at a certain value in the transistor 300 including the oxide semiconductor layer having a single-layer structure. On the other hand, FIG. 4B shows that, in the transistor 200 including the oxide semiconductor layer having a stacked-layer structure, the capacitance value in a region in an accumulation state is saturated at a certain value, and is then increased again by an increase in the application voltage. In other words, in the transistor 200 including the oxide semiconductor layer having a stacked-layer structure, the capacitance value in the region in the accumulation state of the CV characteristics is increased stepwise (in two steps here). In addition, this tendency becomes conspicuous when the measured frequency is less than or equal to 10 kHz, preferably the measured frequency is higher than or equal to 0.3 kHz and lower than or equal to 1 kHz.

The above measurement also shows that the graph of the CV characteristics of the transistor including a semiconductor layer having a stacked-layer structure is different from that of the transistor including a semiconductor layer having a single-layer structure.

### <Verification by Calculation>

Next, whether the CV characteristics of the transistor including a semiconductor layer having a stacked-layer structure could be reproduced or not by calculation was verified. A device simulator “Atlas” developed by Silvaco Data Systems Inc. was used for the calculation.

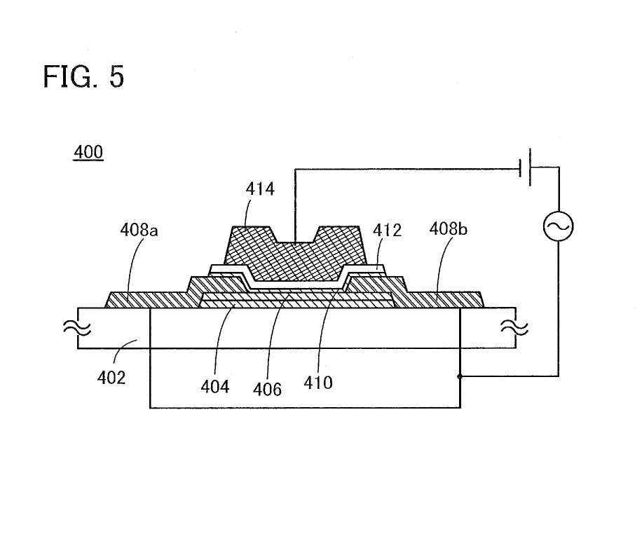

FIG. 5 shows the structure of a transistor 400 including a stacked-layer structure, which is used for the calculation. The transistor 400 has a structure similar to that of the transistor 200 of FIGS. 3A1 to 3B2 and includes, over a substrate 402, a first oxide semiconductor layer 404 and a second oxide semiconductor layer 406; a pair of conductive layers 408a and 408b electrically connected to the first oxide semiconductor layer 404 and the second oxide semiconductor layer 406; a third oxide semiconductor layer 410 over the pair of conductive layers 408a and 408b; a gate insulating layer 412; and a conductive layer 414 in contact with the gate insulating layer 412.

Main calculation conditions are listed in Table 1 below.

TABLE 1

| | | | |
|---|---|---|---|
| Structure | L/W | 50/50 | μm |
| Gate electrode | Work function | 5 | eV |
| Gate insulating layer | Thickness | 17 | nm |
| | Dielectric constant | 4.1 | |
| S/D electrodes | Work function | 4.6 | eV |
| Oxide | Donor density | 6.60E−09 | cm⁻³ |
| semiconductor | (channel portion) | | |
| layers | Donor density | 5.00E+18 | cm⁻³ |
| (common | (directly below S/D) | | |
| conditions) | Nc | 5.00E+18 | cm⁻³ |
| | Nv | 5.00E+18 | cm⁻³ |
| | Dielectric constant | 15 | |
| First oxide | Composition | In:Ga:Zn = 1:3:2 | |
| semiconductor layer | Electron affinity | 3.8-4.4 | eV |
| | (varied conditions) | | |
| | Eg | 3.6 | eV |
| | Electron mobility | 0.1 | cm²/Vsec |
| | Hole mobility | 0.01 | cm²/Vsec |
| | Thickness | 20 | nm |
| Second oxide | Composition | In:Ga:Zn = 1:1:1 | |
| semiconductor layer | Electron affinity | 4.6 | eV |
| | Eg | 3.2 | eV |
| | Electron mobility | 10 | cm²/Vsec |
| | Hole mobility | 0.01 | cm²/Vsec |
| | Thickness | 15 | nm |
| Third oxide | Composition | In:Ga:Zn = 1:3:2 | |
| semiconductor layer | Electron affinity | 3.8-4.4 | eV |
| | (varied conditions) | | |
| | Eg | 3.6 | eV |
| | Electron mobility | 0.1 | cm²/Vsec |
| | Hole mobility | 0.01 | cm²/Vsec |
| | Thickness | 5 | nm |

Note that in the calculation, to analyze how formation of a buried channel was affected by the difference in energy of the bottom of the conduction band (ΔEc) between the first oxide semiconductor layer 404 and the second oxide semiconductor layer 406 or the difference in energy of the bottom of the conduction band (ΔEc) between the second oxide semiconductor layer 406 and the third oxide semiconductor layer 410, various conditions of electron affinity (energy difference between the vacuum level and the bottom of the conduction band) were set in each of the first oxide semiconductor layer 404 and the third oxide semiconductor layer 410. Although the above-described intended thickness of the gate insulating layer 212 in the transistor 200 was 20 nm, the thickness of the gate insulating layer 412 in the calculation was set to 17 nm so that fitting with the capacitance value in the first stage of the CV characteristics of FIG. 4B (combined capacitance of the third oxide semiconductor layer 210 and the gate insulating layer 212) is performed.

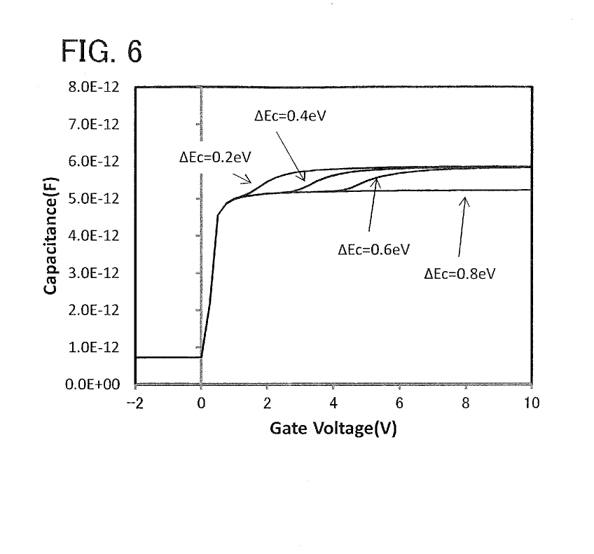

FIG. 6 shows the CV characteristics of the transistor 400 which are obtained by calculation on the assumption that ΔE is set to 0.2 eV, 0.4 eV, 0.6 eV, and 0.8 eV (i.e., the electron affinity of each of the first oxide semiconductor layer 404 and the third oxide semiconductor layer 410 is set to 4.4 eV, 4.2 eV, 4.0 eV, and 3.8 eV).

The calculation results of the CV characteristics of FIG. 6 indicates that as the difference in energy of the bottom of the conduction band (ΔEc) between the second oxide semiconductor layer 406, in which the channel is formed, and the oxide semiconductor layer in contact therewith becomes larger, a gate voltage at which a second-stage increase in (second-stage rising of) the capacitance value in the region in the accumulation state of the CV characteristics is caused is shifted in the high voltage side. As described above, the gate voltage at which the second-stage rising is caused in the CV characteristics represents a voltage at which the buried channel is broken and electrons begin to be accumulated in the third oxide semiconductor layer in contact with the gate insulating layer (hereinafter, such a voltage is also referred to as embedment breakdown voltage). Therefore, the shift of the embedment breakdown voltage in the high voltage side suggests the possibility that the size of ΔEc correlates with the strength of embeddability of the channel. More specifically, as the energy of the bottom of the conduction band of the second oxide semiconductor layer gets lower as compared to the energy of the bottom of the conduction band of the oxide semiconductor layer in contact with the second oxide semiconductor layer, the embedment breakdown voltage might become high. That is, the range of the application voltage at which the buried channel can be formed can be widened.

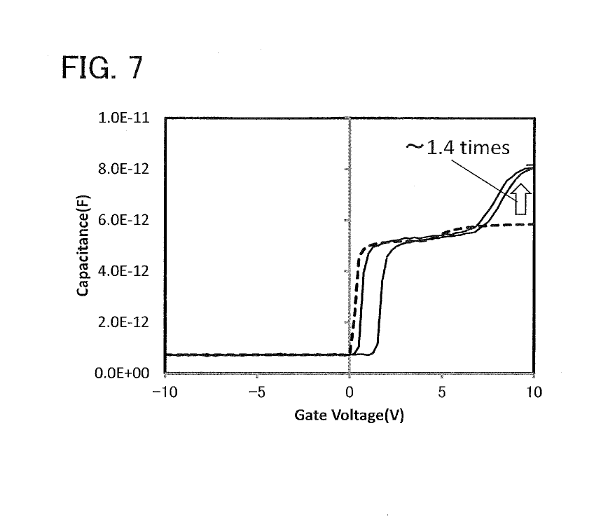

FIG. 7 shows the CV characteristics (ΔEc=0.6 eV) obtained by calculation and the measured CV characteristics (measurement frequency=1 kHz) in FIG. 4B so that they overlap each other.

According to FIG. 7, the CV characteristics obtained by measurement (solid line) and the CV characteristics obtained by calculation (dotted line) exhibit the same tendency at the saturation capacitance value C_{OX1} in the first stage, the rising gate voltage in the second stage (embedment breakdown voltage), and the like.

Note that the second saturation capacitance value C_{OX2} obtained by measurement was approximately 1.4 times as large as the value obtained by calculation. This is because, in the transistor 200 used for measurement, as illustrated in the plan view of FIG. 3A1, an area S2 (=3886 μm²) where the third oxide semiconductor layer 210 and the conductive layer 214 overlap each other is larger than an area S1 (=2800 μm²) where the second oxide semiconductor layer 206 and the conductive layer 214 overlap each other, i.e., S2 is 1.39 times as large as S1.

<Parameters that Might Affect Embedment Breakdown Voltage>

The above calculation has suggested the possibility that the size of ΔEc correlates with the strength of embeddability of the channel. In the description below, calculation in which parameters other than ΔEc are varied is performed, and parameters that might affect the embedment breakdown voltage are considered.

A structure of a transistor similar to that in FIG. 5 was used for the calculation. In the calculation, the thicknesses of the first oxide semiconductor layer 404, the second oxide semiconductor layer 406, the third oxide semiconductor layer 410, and the gate insulating layer 412 were varied and an effect of each thickness upon the embedment breakdown voltage was analyzed. Main parameters used for the calculation are listed in Table 2.

TABLE 2

| | | | |
|---|---|---|---|
| Structure | L/W | 50/50 | μm |
| Gate electrode | Work function | 5 | eV |
| Gate insulating layer | Thickness | 15-25 | nm |
| | (varied conditions) | | |
| | Dielectric constant | 4.1 | |
| S/D electrodes | Work function | 4.6 | eV |
| Oxide | Donor density | 6.60E−09 | cm⁻³ |
| semiconductor | (channel portion) | | |
| layers | Donor density | 5.00E+18 | cm⁻³ |
| (common | (directly below S/D) | | |
| conditions) | Nc | 5.00E+18 | cm⁻³ |
| | Nv | 5.00E+18 | cm⁻³ |
| | Dielectric constant | 15 | |
| First oxide | Composition | In:Ga:Zn = 1:3:2 | |
| semiconductor layer | Electron affinity | 4.0 (ΔEc = 0.6) | eV |
| | Eg | 3.6 | eV |
| | Electron mobility | 0.1 | cm²/Vsec |
| | Hole mobility | 0.01 | cm²/Vsec |
| | Thickness | 5-10 | nm |
| | (varied conditions) | | |
| Second oxide | Composition | In:Ga:Zn = 1:1:1 | |
| semiconductor layer | Electron affinity | 4.6 | eV |
| | Eg | 3.2 | eV |
| | Electron mobility | 10 | cm²/Vsec |
| | Hole mobility | 0.01 | cm²/Vsec |
| | Thickness | 10-30 | nm |
| | (varied conditions) | | |
| Third oxide | Composition | In:Ga:Zn = 1:3:2 | |
| semiconductor layer | Electron affinity | 4.0 (ΔEc = 0.6) | eV |
| | Eg | 3.6 | eV |
| | Electron mobility | 0.1 | cm²/Vsec |
| | Hole mobility | 0.01 | cm²/Vsec |
| | Thickness | 10-30 | nm |
| | (varied conditions) | | |

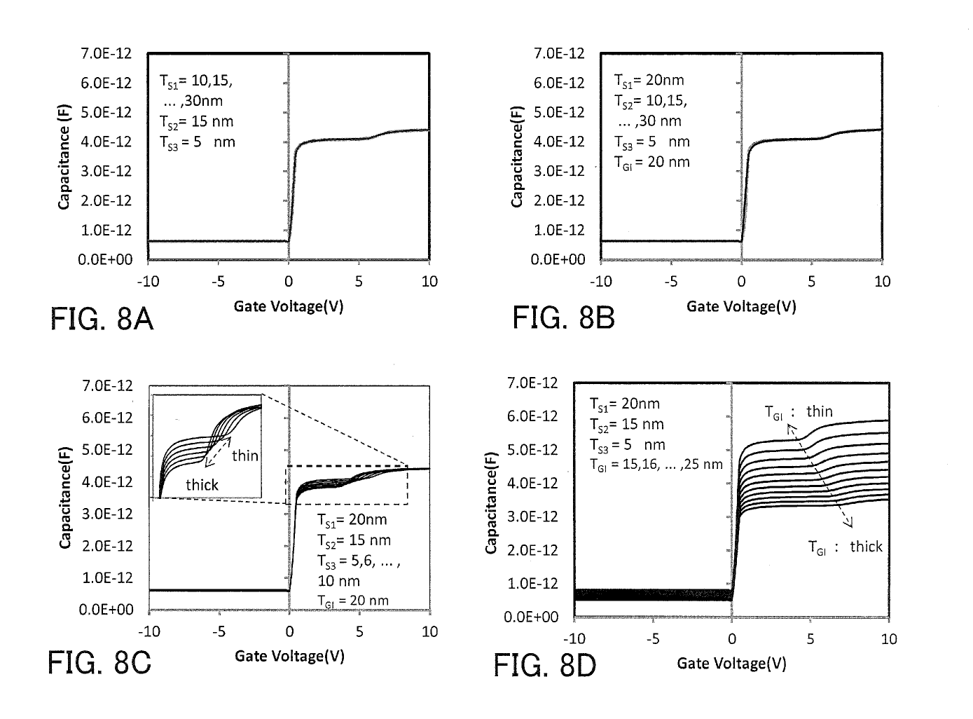

FIGS. 8A to 8D show CV characteristics obtained by the calculation. FIG. 8A shows results of calculation in which the thickness of the first oxide semiconductor layer 404 (T_{S1}) is varied. FIG. 8B shows results of calculation in which the thickness of the second oxide semiconductor layer 406 (T_{S2}) is varied. FIG. 8C shows results of calculation in which the thickness of the third oxide semiconductor layer 410 (T_{S3}) is varied. FIG. 8D shows results of calculation in which the thickness of the gate insulating layer 412 (T_{G1}) is varied.

According to FIGS. 8A and 8B, difference which depends on thickness is not found in the CV characteristics obtained by calculation with varied thicknesses of the first oxide semiconductor layer 404 and in those obtained by calculation with varied thickness of the second oxide semiconductor layer 406. Accordingly, the thickness of the second oxide semiconductor layer 406 functioning as the channel and the thickness of the first oxide semiconductor layer 404 that is more apart from the gate than the channel do not affect the embedment breakdown voltage.

Meanwhile, according to FIGS. 8C and 8D, difference which depends on thickness is found in the CV characteristics obtained by calculation with varied thicknesses of the third oxide semiconductor layer 410 and in those obtained by calculation with varied thicknesses of the gate insulating layer 412. Specifically, in FIG. 8C, as the thickness of the third oxide semiconductor layer 410 gets smaller, the embedment breakdown voltage is shifted more in the positive direction. Furthermore, in FIG. 8D, as the thickness of the gate insulating layer 412 gets larger, the embedment breakdown voltage is shifted more in the positive direction.

Here, an effect of the respective thicknesses of the third oxide semiconductor layer 410 and the gate insulating layer 412 upon the embedment breakdown voltage is discussed on the basis of a band diagram.

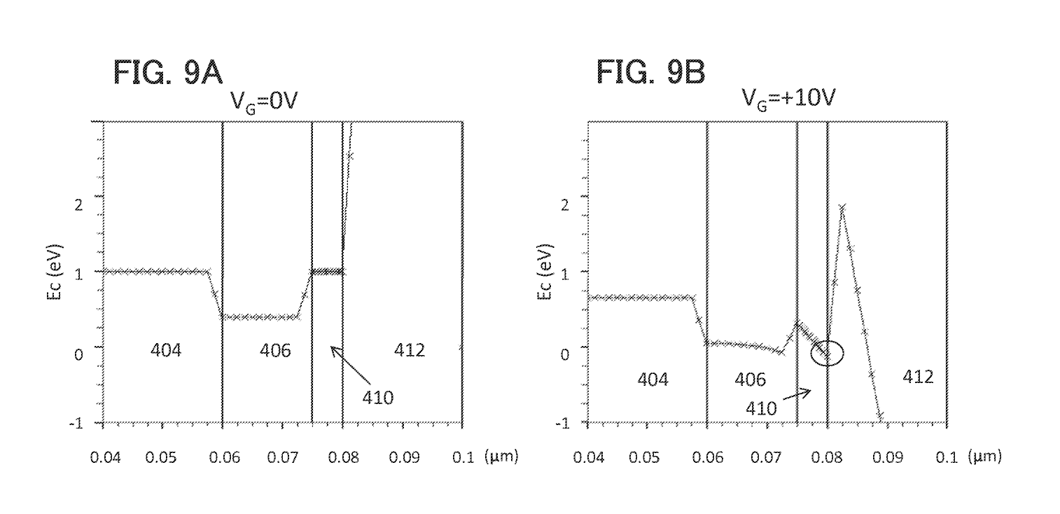

FIGS. 9A and 9B each show the calculation results of the band diagram illustrating the bottom of the conduction band of a stacked-layer structure including the first oxide semiconductor layer 404, the second oxide semiconductor layer 406, the third oxide semiconductor layer 410, and the gate insulating layer 412.

In the case where a gate voltage is 0 V (see FIG. 9A), the bottom of the conduction band of the second oxide semiconductor layer 406 is lower than those of the first oxide semiconductor layer 404 and the third oxide semiconductor layer 410; therefore, the channel is embedded in the second oxide semiconductor layer 406.

Meanwhile, in the case where a gate voltage is 10 V (see FIG. 9B), the bottom of the conduction band of the interface between the third oxide semiconductor layer 410 and the gate insulating layer 412 is lower than that of the second oxide semiconductor layer 406; therefore, the channel is formed not only in the second oxide semiconductor layer 406 but also at the interface between the third oxide semiconductor layer 410 and the gate insulating layer 412. That is, embedment of the channel is broken.

That is, “the channel is embedded in the second oxide semiconductor layer 406” has the same meaning as “the bottom of the conduction band of the interface between the third oxide semiconductor layer 410 and the gate insulating layer 412 is higher than that of the second oxide semiconductor layer 406”. This can be represented as Formula (I).

[Formula 1]

eΔV_{S3}<ΔE_{C} (1)

Note that in Formula (1), e represents elementary charge and ΔV_{S3} represent the voltage drop in the third oxide semiconductor layer 410.

The relationship of Formula (2) is approximately satisfied between ΔV_{S3} and gate voltage V_{G}.

$$\begin{matrix}[ Formula 2 ] & \\ Δ {V}_{S 3} = \frac{{V}_{G}}{1 + \frac{{C}_{S 3}}{{C}_{GI}}} & ( 2 )\end{matrix}$$

Note that in Formula (2), C_{S3} represents the capacitance of the third oxide semiconductor layer 410 and C_{GI} represents the capacitance of the gate insulating layer 412.

Substitution of Formula (2) into Formula (1) gives Formula (3).

$$\begin{matrix}[ Formula 3 ] & \\ e \frac{1}{1 + \frac{{ɛ}_{S 3} {t}_{GI}}{{ɛ}_{GI} {t}_{S 3}}} {V}_{G} < Δ {E}_{C} & ( 3 )\end{matrix}$$

Note that in Formula (3), ε_{S3} represents the dielectric constant of the third oxide semiconductor layer 410 and t_{S3} represents the thickness of the third oxide semiconductor layer 410. Furthermore, ε_{GI} represents the dielectric constant of the gate insulating layer 412 and t_{GI} represents the thickness of the gate insulating layer 412.

Here, ε_{GI}<ε_{S3} and t_{S3}<t_{GI}; therefore, Formula (3) can be replaced with Formula (4) where ε_{GI}t_{S3<}ε_{S3}t_{GI}.

$$\begin{matrix}[ Formula 4 ] & \\ e \frac{{ɛ}_{GI} {t}_{S 3}}{{ɛ}_{S 3} {t}_{GI}} {V}_{G} < Δ {E}_{C} & ( 4 )\end{matrix}$$

Formula (4) indicates the condition for embedment of the channel in the second oxide semiconductor layer 406. When embedment of the channel is broken, i.e., the gate voltage is equal to the embedment breakdown voltage, the right side is equal to the left side. Therefore, the embedment breakdown voltage is approximately represented as Formula (5) below.

$$\begin{matrix}[ Formula 5 ] & \\ {V}_{G} ( breakdown ) = \frac{1}{e} \frac{{ɛ}_{S 3} {t}_{GI}}{{ɛ}_{GI} {t}_{S 3}} Δ {E}_{C} & ( 5 )\end{matrix}$$

Formula (5) also corresponds to the tendency of the embedment breakdown voltage to be increased as the thickness of the third oxide semiconductor layer 410 gets smaller, which is shown in FIG. 8C; and the tendency of the embedment breakdown voltage to be increased as the thickness of the gate insulating layer 412 gets larger, which is shown in FIG. 8D.

### <Usage of Evaluation Results>

As described above, whether the buried channel is formed or not can be evaluated by the CV characteristics of the semiconductor device including the semiconductor layer with a stacked-layer structure. Furthermore, the above results indicate that even in a transistor in which the channel is formed to be apart from the insulating layer, the buried channel is broken by application of high gate voltage. In other words, use of the evaluation method of this embodiment enables estimation of a range of the application voltage in which the buried channel can be formed.

In addition, the embedment breakdown voltage depends on: (1) difference in the energy of the bottom of the conduction band between the semiconductor layer where the channel is formed and the semiconductor layer in contact therewith; (2) the thickness of the semiconductor layer positioned between the semiconductor layer where the channel is formed and the gate insulating layer; and (3) the thickness of the gate insulating layer. Therefore, optimal conditions of a transistor can be evaluated in such a manner that samples in which the above conditions are different from one another are prepared and their CV characteristics are compared with each other.

For example, a first transistor and a second transistor which have the same structure as the structure of FIG. 1 except for the composition of the second semiconductor layer are prepared, and the embedment breakdown voltage is measured from the respective CV characteristics, so that a favorable composition of the second semiconductor layer can be evaluated.

Alternatively, a first transistor and a second transistor which have the same structure as the structure of FIG. 1 except for the thickness of the second semiconductor layer are prepared, and the embedment breakdown voltage is measured from the respective CV characteristics, so that a favorable thickness of the second semiconductor layer can be evaluated.

Alternatively, a first transistor and a second transistor which have the same structure as the structure of FIG. 1 except for the thickness of the gate insulating layer are prepared, and the embedment breakdown voltage is measured from the respective CV characteristics, so that a favorable thickness of the gate insulating layer can be evaluated.

The structures, methods, and the like described in this embodiment can be combined as appropriate with any of the structures, methods, and the like described in the other embodiments.

### Embodiment 2

In this embodiment, another structure example of a transistor on which the evaluation method of one embodiment of the present invention can be performed is described. Although an example where an oxide semiconductor layer is used for a channel and the like is described in this embodiment, one embodiment of the present invention is not limited thereto. For example, depending on cases or conditions, a channel, the vicinity of the channel, a source region, a drain region, or the like may be formed using a material containing Si (silicon), Ge (germanium), SiGe (silicon germanium), GaAs (gallium arsenide), or the like.

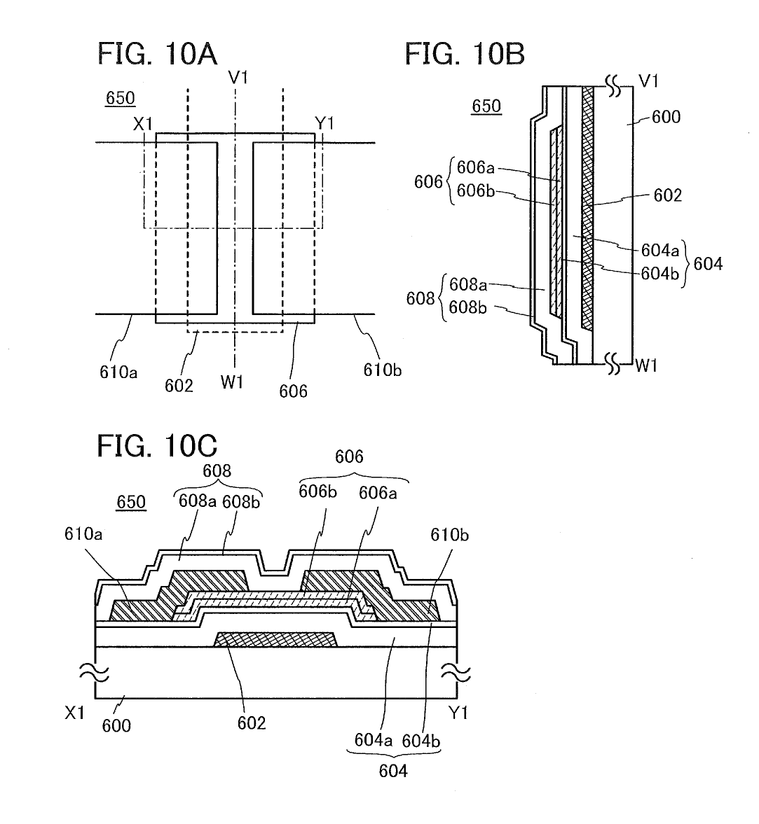

FIGS. 10A to 10C illustrate a structure example of a semiconductor device. FIGS. 10A to 10C illustrate a bottom-gate transistor as an example of a semiconductor device. FIG. 10A is a plan view of a transistor 650, FIG. 10B is a cross-sectional view taken along line V1-W1 in FIG. 10A, and FIG. 10C is a cross-sectional view taken along line X1-Y1 in FIG. 10A. Note that in FIG. 10A, some components (e.g., an insulating layer 608) are not illustrated for clarity.

The transistor 650 illustrated in FIGS. 10A to 10C includes a conductive layer 602 provided over a substrate 600, a gate insulating layer 604 over the conductive layer 602, a first oxide semiconductor layer 606a and a second oxide semiconductor layer 606b provided over the gate insulating layer 604 and overlapping the conductive layer 602, conductive layers 610a and 610b electrically connected to at least one of the first oxide semiconductor layer 606a and the second oxide semiconductor layer 606b, and the insulating layer 608 overlapping the gate insulating layer 604 with the second oxide semiconductor layer 606b positioned therebetween. The conductive layer 602 includes a region functioning as a gate electrode. The conductive layers 610a and 610b include regions functioning as source and drain electrodes.

The oxide semiconductor layer included in the transistor 650 has a stacked-layer structure of the first oxide semiconductor layer 606a where a channel is formed and the second oxide semiconductor layer 606b between the first oxide semiconductor layer 606a and the insulating layer 608. When the evaluation method of one embodiment of the present invention is used in the manufacturing process of the transistor 650, a favorable driving voltage, favorable composition and thickness of the second oxide semiconductor layer 606b, a favorable thickness of the gate insulating layer 604, and the like for forming the channel in the first oxide semiconductor layer 606a can be evaluated. Thus, it becomes possible to form the transistor 650 whose channel is embedded in the first oxide semiconductor layer 606a.

When the second oxide semiconductor layer 606b is provided between the insulating layer 608 and the first oxide semiconductor layer 606a where the channel is formed, influence of trap states which might be formed between an oxide semiconductor layer 606 which includes the first and second oxide semiconductor layers 606a and 606b and the insulating layer 608 on the channel can be reduced or suppressed. Accordingly, the electrical characteristics of the transistor 650 can be stabilized.

In this embodiment, materials which contain indium and zinc as constituent elements are used for the first oxide semiconductor layer 606a and the second oxide semiconductor layer 606b. In addition, the materials are selected so that the energy of the bottom of the conduction band of the second oxide semiconductor layer 606b is closer to the vacuum level than the energy of the bottom of the conduction band of the first oxide semiconductor layer 606a by 0.05 eV or more and 2 eV or less. The difference in energy of the bottom of the conduction band between the first oxide semiconductor layer 606a and the second oxide semiconductor layer 606b can be estimated by the measurement or the calculation of the CV characteristics described in Embodiment 1.

In the case where the first oxide semiconductor layer 606a is an oxide semiconductor layer represented by an In-M-Zn oxide (M is Al, Ga, Ge, Y, Zr, Sn, La, Ce, or Hf), the second oxide semiconductor layer 606b is represented by an In-M-Zn oxide (M is Al, Ga, Ge, Y, Zr, Sn, La, Ce, or Hf) like the first oxide semiconductor layer 606a and is preferably an oxide semiconductor layer in which the atomic ratio of M to indium is higher than that in the first oxide semiconductor layer 606a.

Specifically, the amount of any of the above elements in the second oxide semiconductor layer 606b in an atomic ratio is one and a half times or more, preferably twice or more, more preferably three times or more that in the first oxide semiconductor layer 606a. The element M is more strongly bonded to oxygen than to indium is, and thus an oxygen vacancy is more unlikely to be generated in an oxide semiconductor in which the atomic ratio of M to indium is high. In other words, the second oxide semiconductor layer 606b is an oxide semiconductor layer in which oxygen vacancy is less likely to be generated than in the first oxide semiconductor layer 606a. Note that as the atomic ratio of M to indium becomes higher, the energy gap (bandgap) of the oxide semiconductor layer is increased; thus, when the atomic ratio of M to indium is too high, the second oxide semiconductor layer 606b functions as an insulating layer. Therefore, the atomic ratio of M to indium is preferably controlled so he second oxide semiconductor layer 606b functions as a semiconductor layer.

When each of the first oxide semiconductor layer 606a and the second oxide semiconductor layer 606b is an In-M-Zn oxide containing at least indium, zinc, and M (M is a metal such as Al, Ti, Ga, Ge, Y, Zr, Sn, La, Ce, or Hf) and the first oxide semiconductor layer 606a has an atomic ratio of In:M:Zn=x₁:y₁:z₁ and the second oxide semiconductor layer 606b has an atomic ratio of In:M:Zn=x₂:y₂:z₂, y₂/x₂ is preferably larger than y₁/x₁. y₂/z₂ is one and a half times or more, preferably twice or more, further preferably three or more as large as y₁/x₁. At this time, when y₁ is greater than or equal to x₁ in the first oxide semiconductor layer 606a, the transistor can have stable electrical characteristics. However, when y₁ is three times or more as large as x₁, the field-effect mobility of the transistor is reduced; therefore, y₁ is preferably smaller than three times x₁.

In the case where the first oxide semiconductor layer 606a is an In-M-Zn oxide, when Zn and oxygen are eliminated from consideration, the atomic percentage of In and the atomic percentage of M are preferably greater than or equal to 25 atomic % and less than 75 atomic %, respectively, further preferably greater than or equal to 34 atomic % and less than 66 atomic %, respectively. In the case where the second oxide semiconductor layer 606b is an In-M-Zn oxide, when Zn and oxygen are eliminated from consideration, the atomic percentage of In and the atomic percentage of M are preferably less than 50 atomic % and greater than or equal to 50 atomic %, respectively, further preferably less than 25 atomic % and greater than or equal to 75 atomic %, respectively.

Furthermore, it is preferable that second oxide semiconductor layer 606b be formed using an oxide semiconductor whose energy of the bottom of the conduction band is closer to the vacuum level than that of the first oxide semiconductor layer 606a by 0.05 eV or more, 0.07 eV or more, 0.1 eV or more, or 0.15 eV or more and 2 eV or less, 1 eV or less, 0.5 eV or less, or 0.4 eV or less.

When an electric field is applied to the conductive layer 602 in such a structure, the first oxide semiconductor layer 606a that is the layer having the lowest energy of the bottom of the conduction band serves as a main carrier path (channel). Here, since the second oxide semiconductor layer 606b is included between the channel formation region (first oxide semiconductor layer 606a) and the insulating layer 608, the is distanced from trap states formed due to impurities and defects at the interface between the channel and the insulating layer 608. Thus, electrons flowing in the first oxide semiconductor layer 606a are less likely to be captured by the trap states. Accordingly, the on-state current of the transistor can be increased, and the field-effect mobility can be increased. When an electron is captured by the trap state, the electron serves as a negative fixed electric charge to cause a shift of the threshold voltage of the transistor. However, by the distance between the first oxide semiconductor layer 606a and the trap states, capture of the electrons by the trap states can be reduced, and accordingly a change in the threshold voltage can be reduced.

Note that the first and second oxide semiconductor layers 606a and 606b are not formed by simply stacking layers but are formed to have a continuous energy band (here, in particular, a structure in which energy of the bottom of the conduction band is changed continuously between the layers). In other words, a stacked-layer structure in which there exists no impurity which forms a defect level such as a trap center or a recombination center at each interface is provided. If an impurity exists between the stacked first and second oxide semiconductor layers 606a and 606b, continuity of the energy band is lost, and thus carriers are trapped or disappear by recombination at the interface.

In order to form such a continuous energy band, it is necessary to form films continuously without being exposed to air, with use of a multi-chamber deposition apparatus (sputtering apparatus) including a load lock chamber. It is preferable that each chamber of the sputtering apparatus be evacuated to a high vacuum (to the degree of approximately 5×10⁻⁷ Pa to 1×10⁻⁴ Pa) by an adsorption vacuum pump such as a cryopump so that water and the like acting as impurities of the oxide semiconductor layer are removed as much as possible. Alternatively, a turbo molecular pump and a cold trap are preferably combined so as to prevent a backflow of a gas, especially a gas containing carbon or hydrogen from an exhaust system to the inside of the chamber.

In the first oxide semiconductor layer 606a where the channel is formed, hydrogen is preferably reduced as much as possible. Specifically, in the first oxide semiconductor layer 606a, the hydrogen concentration which is measured by secondary ion mass spectrometry (SIMS) is lower than or equal to 2×10²⁰ atoms/cm³, preferably lower than or equal to 5×10¹⁹ atoms/cm³, further preferably lower than or equal to 1×10¹⁹ atoms/cm³, still further preferably lower than 5×10¹⁸ atoms/cm³, yet still further preferably lower than or equal to 1×10¹⁸ atoms/cm³, yet still further preferably lower than or equal to 5×10¹⁷ atoms/cm³, and yet still further preferably lower than or equal to 1×10¹⁶ atoms/cm³.

In the transistor 650, the gate insulating layer 604 has a stacked-layer structure of an insulating layer 604a and an insulating layer 604b. As each of the insulating layer 604a and the insulating layer 604b, silicon oxynitride, silicon nitride oxide, silicon nitride, silicon oxide, aluminum oxide, aluminum oxynitride, aluminum nitride, aluminum nitride oxide, hafnium oxide, gallium oxide, a Ga—Zn-based metal oxide, or the like can be used. Although the gate insulating layer 604 has the stacked-layer structure of the insulating layer 604a and the insulating layer 604b in this embodiment, one embodiment of the present invention is not limited thereto. The gate insulating layer may have a single-layer structure or a stacked-layer structure of three or more layers.

In the gate insulating layer 604, a nitride insulating film using silicon nitride, silicon nitride oxide, aluminum nitride, aluminum nitride oxide, or the like is preferably formed as the insulating layer 604a in contact with the conductive layer 602, in which case diffusion of the metal element contained in the conductive layer 602 can be prevented.

Furthermore, a silicon nitride film or a silicon nitride oxide film is preferably used as the insulating layer 604a. In addition, a silicon nitride film or a silicon nitride oxide film has a higher dielectric constant than a silicon oxide film and needs a larger thickness for capacitance equivalent to that of the silicon oxide. Thus, the physical thickness of the gate insulating layer can be increased. For example, the insulating layer 604a has a thickness greater than or equal to 300 nm and less than or equal to 400 nm. Accordingly, a reduction in withstand voltage of the transistor 650 is prevented and the withstand voltage is improved, whereby electrostatic breakdown of the semiconductor device can be prevented.

A nitride insulating film which is preferably used as the insulating layer 604a can be formed dense and can prevent diffusion of the metal element of the conductive layer 602. However, the density of defect states and internal stress of the nitride insulating film are large and consequently the threshold voltage may be changed when the interface between the insulating layer 604a and the oxide semiconductor layer 606 is formed. For this reason, when a nitride insulating film is formed as the insulating layer 604a, an oxide insulating film formed of silicon oxide, silicon oxynitride, aluminum oxide, aluminum oxynitride, or the like is preferably formed as the insulating layer 604b between the insulating layer 604a and the oxide semiconductor layer 606. When the insulating layer 604b formed of an oxide insulating film is formed between the oxide semiconductor layer 606 and the insulating layer 604a formed of a nitride insulating film, the interface between the gate insulating layer 604 and the oxide semiconductor layer 606 can be stable.

The insulating layer 604b can have a thickness greater than or equal to 25 nm and less than or equal to 150 nm, for example. Note that an oxide insulating film is used as the insulating layer 604b which is in contact with the oxide semiconductor layer 606; consequently, oxygen can be supplied to the oxide semiconductor layer 606. Oxygen vacancy contained in an oxide semiconductor make the conductivity of the oxide semiconductor n-type, which causes change in electrical characteristics. Thus, supplying oxygen from the insulating layer 604b to fill the oxygen vacancy is effective in increasing reliability.

The gate insulating layer 604 may be formed using a high-k material such as hafnium silicate (HfSiOₓ), hafnium silicate to which nitrogen is added hafnium aluminate to which nitrogen is added (HfAlₓO_{y}N_{z}), hafnium oxide, or yttrium oxide, so that gate leakage of the transistor can be reduced.

Furthermore, in the transistor 650, the insulating layer 608 in contact with a top layer of the oxide semiconductor layer 606 is preferably an insulating layer containing oxygen (oxide insulating layer), i.e., an insulating layer capable of releasing oxygen. This is because oxygen released from the insulating layer 608 is supplied to the oxide semiconductor layer 606 (specifically, the first oxide semiconductor layer 606a where the channel is formed), so that oxygen vacancy in the oxide semiconductor layer 606 or at the interface thereof can be filled. Note that as the insulating layer capable of releasing oxygen, a silicon oxide layer, a silicon oxynitride layer, or an aluminum oxide layer can be used.

In this embodiment, e insulating layer 608 has a stacked-layer structure of an insulating layer 608a and an insulating layer 608b. An oxide insulating film capable of reducing oxygen vacancy in the oxide semiconductor is used as the insulating layer 608a, and a nitride insulating film capable of preventing impurities from entering the oxide semiconductor layer 606 from the outside is used as the insulating layer 608b. An oxide insulating film which can be preferably used as the insulating layer 608a and a nitride insulating film which can be preferably used as the insulating layer 608b are described in detail below.

The oxide insulating film is formed using an oxide insulating film whose oxygen content is in excess of that in the stoichiometric composition. Part of oxygen is released by heating from the oxide insulating film containing more oxygen than that in the stoichiometric composition. The oxide insulating film containing more oxygen than that in the stoichiometric composition is an oxide insulating film of which the amount of released oxygen converted into oxygen atoms is greater than or equal to 1.0×10¹⁸ atoms/cm³, preferably greater than or equal to 3.0×10²⁰ atoms/cm³ in TDS analysis. Note that the temperature of the film surface in the TDS analysis is preferably higher than or equal to 100° C. and lower than or equal to 700° C., or higher than or equal to 100° C. and lower than or equal to 500° C.

A silicon oxide film, a silicon oxynitride film, or the like with a thickness greater than or equal to 30 nm and less than or equal to 500 nm, preferably greater than or equal to 50 nm and less than or equal to 400 nm can be used for the oxide insulating film which can be used as the insulating layer 608a.

The nitride insulating film which can be used as the insulating layer 608b has a blocking effect against oxygen, hydrogen, water, alkali metal, alkaline earth metal, and the like. It is possible to prevent outward diffusion of oxygen from the oxide semiconductor layer 606 and entry of hydrogen, water, and the like into the oxide semiconductor layer 606 from the outside by providing the nitride insulating film as the insulating layer 608b. The nitride insulating film is formed using silicon nitride, silicon nitride oxide, aluminum nitride, aluminum nitride oxide, or the like. Note that instead of the nitride insulating film having a blocking effect against oxygen, hydrogen, water, alkali metal, alkaline earth metal, and the like, an oxide insulating film having a blocking effect against oxygen, hydrogen, water, and the like, may be provided. As the oxide insulating film having a blocking effect against oxygen, hydrogen, water, and the like, an aluminum oxide film, an aluminum oxynitride film, a gallium oxide film, a gallium oxynitride film, an yttrium oxide film, an yttrium oxynitride film, a hafnium oxide film, and a hafnium oxynitride film can be given.

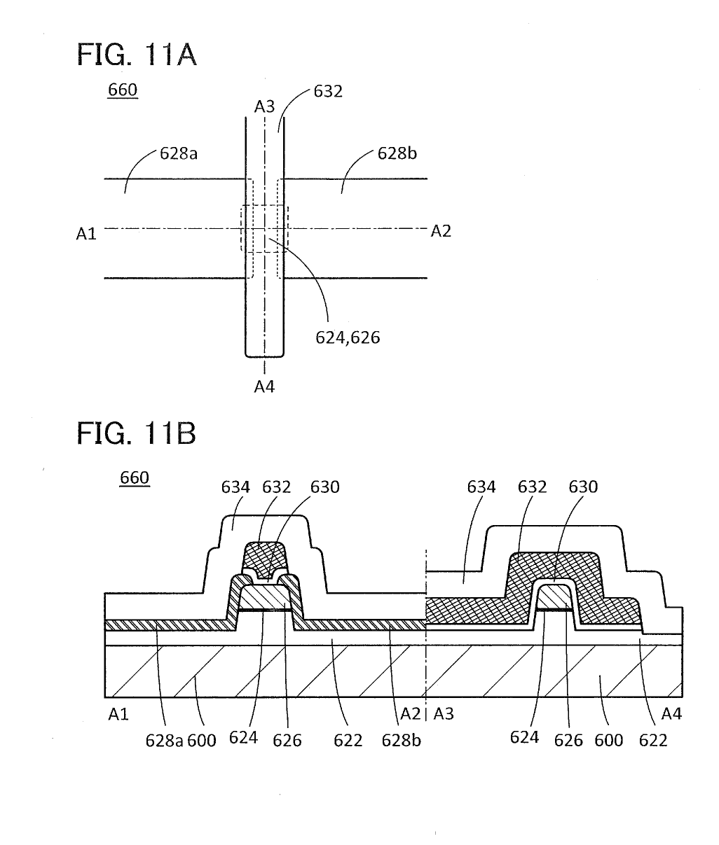

FIGS. 11A and 11B illustrate another structure example of the semiconductor device of this embodiment. FIGS. 11A and 11B illustrate a transistor 660 having a top-gate structure as an example of the semiconductor device.

FIGS. 11A and 11B are a plan view and a cross-sectional view illustrating the transistor 660 of one embodiment of the present invention. FIG. 11A is a plan view and FIG. 11B is a cross-sectional view taken along dashed-dotted lines A1-A2 and A3-A4 in FIG. 11A. Note that for simplification of the drawing, some components are not illustrated in the plan view in FIG. 11A.

The transistor 660 illustrated in FIGS. 11A and 11B includes an insulating layer 622 having a projection portion over the substrate 600, a first oxide semiconductor layer 624 and a second oxide semiconductor layer 626 over the projection portion of the insulating layer 622, a pair of conductive layers 628a and 628b in contact with a side surface of the first oxide semiconductor layer 624 and top and side surfaces of the second oxide semiconductor layer 626, an insulating layer 630 over the conductive layers 628a and 628b and in contact with the second oxide semiconductor layer 626, and a conductive layer 632 in contact with a top surface of the insulating layer 630 and facing the side surface of the first oxide semiconductor layer 624 and the top and side surfaces of the second oxide semiconductor layer 626. Note that the transistor 660 may further include an insulating layer 634 over the conductive layers 628a and 628b and the conductive layer 632. The insulating layer 622 does not necessarily have the projection portion. The conductive layers 628a and 628b include regions functioning as source and drain electrodes of the transistor 660. The conductive layer 632 includes a region functioning as a gate electrode of the transistor 660.

In the transistor 660 illustrated in FIGS. 11A and 11B, the insulating layer 622 functions as a base insulating layer. For the base insulating layer, silicon oxide, silicon oxynitride, silicon nitride, silicon nitride oxide, gallium oxide, hafnium oxide, yttrium oxide, aluminum oxide, aluminum oxynitride, or he like can be used. Note that when silicon nitride, gallium oxide, hafnium oxide, yttrium oxide, aluminum oxide, or the like is used for the base insulating layer, it is possible to prevent diffusion of impurities such as alkali metal, water, and hydrogen from the substrate 600 into the oxide semiconductor layer. Furthermore, it is preferable that an insulating layer containing oxygen, further preferably an insulating layer having a region which contains oxygen in a proportion higher than that in the stoichiometric composition, be used as the base insulating layer because oxygen can be supplied to the oxide semiconductor layer.

The first oxide semiconductor layer 624 corresponds to the second oxide semiconductor layer 606b of the transistor 650. The second oxide semiconductor layer 626 corresponds to the first oxide semiconductor layer 606a of the transistor 650. The insulating layer 630, which functions as a gate insulating layer in the transistor 660, corresponds to the gate insulating layer 604 of the transistor 650. That is, in the transistor 660, the second oxide semiconductor layer 626 includes a region which has higher electron affinity than the first oxide semiconductor layer 624. In other words, in the transistor 660, the second oxide semiconductor layer 626 functions as a main current path (channel).

As illustrated in FIG. 11B, side surfaces of the conductive layers 628a and 628b are in contact with the side surface of the second oxide semiconductor layer 626 where the channel is formed. In a cross section in the channel width direction, the conductive layer 632 is provided to face the top and side surfaces of the second oxide semiconductor layer 626, and the second oxide semiconductor layer 626 can be electrically surrounded by an electric field of the conductive layer 632. Here, the structure of the transistor in which the channel (or the second oxide semiconductor layer 626 in which the channel is formed) is electrically surrounded by the electric field of the conductive layer 632 is called a surrounded channel (s-channel) structure. Since the transistor 660 has the s-channel structure, the channel can be formed in the entire second oxide semiconductor layer 626 (bulk). In the s-channel structure, a large amount of current can flow between a source and a drain of a transistor, so that a high on-state current can be obtained.

The s-channel structure is suitable for a miniaturized transistor because a high on-state current can be obtained. A semiconductor device including the miniaturized transistor can have a high integration degree and high density. For example, the channel length of the transistor is preferably less than or equal to 40 nm, more preferably less than or equal to 30 nm, still more preferably less than or equal to 20 nm and the channel width of the transistor is preferably less than or equal to 40 nm, more preferably less than or equal to 30 nm, still more preferably less than or equal to 20 nm.

Note that the channel length refers to, for example, a distance between a source (a source region or a source electrode) and a drain (a drain region or a drain electrode) in a region where a semiconductor (or a portion where a current flows in a semiconductor when a transistor is on) and a gate electrode overlap with each other or a region where a channel is formed in a top view of the transistor. In one transistor, channel lengths in all regions are not necessarily the same. In other words, the channel length of one transistor is not limited to one value in some cases. Therefore, in this specification, the channel length is any one of values, the maximum value, the minimum value, or the average value in a region where a channel is formed.

A channel width refers to, for example, the length of a portion where a source and a drain face each other in a region where a semiconductor (or a portion where a current flows in a semiconductor when a transistor is on) and a gate electrode overlap with each other, or a region where a channel is formed. In one transistor, channel widths in all regions do not necessarily have the same value. In other words, a channel width of one transistor is not fixed to one value in some cases. Therefore, in this specification, a channel width is any one of values, the maximum value, the minimum value, or the average value in a region where a channel is formed.

Note that depending on transistor structures, a channel width in a region where a channel is formed actually (hereinafter referred to as an effective channel width) is different from a channel width shown in a top view of a transistor (hereinafter referred to as an apparent channel width) in some cases. For example, in a transistor having a three-dimensional structure, an effective channel width is greater than an apparent channel width shown in a top view of the transistor, and its influence cannot be ignored in some cases. For example, in a miniaturized transistor having a three-dimensional structure, the proportion of a channel region formed in a side surface of a semiconductor is higher than the proportion of a channel region formed in a top surface of a semiconductor in some cases. In that case, an effective channel width obtained when a channel is actually formed is greater than an apparent channel width shown in the top view.

In a transistor having a three-dimensional structure, an effective channel width is difficult to measure in some cases. For example, to estimate an effective channel width from a design value, it is necessary to assume that the shape of a semiconductor is known as an assumption condition. Therefore, in the case where the shape of a semiconductor is not known accurately, it is difficult to measure an effective channel width accurately.

Therefore, in this specification, in a top view of a transistor, an apparent channel width that is a length of a portion where a source and a drain face each other in a region where a semiconductor and a gate electrode overlap with each other is referred to as a surrounded channel width (SCW) in some cases. Further, in this specification, in the case where the term “channel width” is simply used, it may denote a surrounded channel width and an apparent channel width. Alternatively, in this specification, in the case where the term “channel width” is simply used, it may denote an effective channel width in some cases. Note that the values of a channel length, a channel width, an effective channel width, an apparent channel width, a surrounded channel width, and the like can be determined by obtaining and analyzing a cross-sectional TEM image and the like.

Note that in the case where electric field mobility, a current value per channel width, and the like of a transistor are obtained by calculation, a surrounded channel width may be used for the calculation. In that case, a value different from one in the case where an effective channel width is used for the calculation is obtained in some cases.

A conductive layer capable of extracting oxygen from an oxide semiconductor layer is preferably used for the conductive layers 628a and 628b. As an example of the conductive layer capable of extracting oxygen from the oxide semiconductor layer, a conductive layer containing aluminum, titanium, chromium, nickel, molybdenum, tantalum, tungsten, or the like can be given.

By the conductive layer capable of extracting oxygen from the oxide semiconductor layer, oxygen in the first oxide semiconductor layer 624 and/or the second oxide semiconductor layer 626 is released to form oxygen vacancy in the oxide semiconductor layer in some cases. Oxygen is more likely to be extracted as the temperature is higher. Since the manufacturing process of a transistor involves some heat treatment steps, oxygen vacancy is likely to be formed in a region of the oxide semiconductor layer which is in contact with the conductive layers 628a and 628b. Furthermore, hydrogen enters sites of oxygen vacancies by heating, and thus the oxide semiconductor layer becomes n-type in some cases. Thus, due to the conductive layers 628a and 628b, the resistance of regions where the oxide semiconductor layer is in contact with conductive layers 628a and 628b is reduced, so that the on-state resistance of the transistor can be reduced.

In the case where a transistor with a short channel length less than or equal to 200 nm, or less than or equal to 100 nm) is manufactured, the source and the drain might be short-circuited because of formation of an n-type region. Therefore, in the case where a transistor with a short channel length is manufactured, a conductive layer capable of appropriately extracting oxygen from an oxide semiconductor layer may be used as the conductive layers 628a and 628b. As the conductive layer capable of appropriately extracting oxygen, a conductive layer containing nickel, molybdenum, or tungsten can be used, for example.

Furthermore, in the case where a transistor with an extremely short channel length (less than or equal to 40 nm, or less than or equal to 30 nm) is manufactured, a conductive layer which is less likely to extract oxygen from an oxide semiconductor layer may be used as the conductive layers 628a and 628b. As an example of the conductive layer which is less likely to extract oxygen from an oxide semiconductor layer, a conductive layer containing tantalum nitride, titanium nitride, or ruthenium can be given. Note that plural kinds of conductive layers may be stacked.

The conductive layer 632 may be formed using a conductive layer containing one or more of aluminum, titanium, chromium, cobalt, nickel, copper, yttrium, zirconium, molybdenum, ruthenium, silver, tantalum, tungsten, and the like.

As the insulating layer 634, for example, a single layer or a stacked layer of an insulating layer containing aluminum oxide, magnesium oxide, silicon oxide, silicon oxynitride, silicon nitride oxide, silicon nitride, gallium oxide, germanium oxide, yttrium oxide, zirconium oxide, lanthanum oxide, neodymium oxide, hafnium oxide, or tantalum oxide may be used.

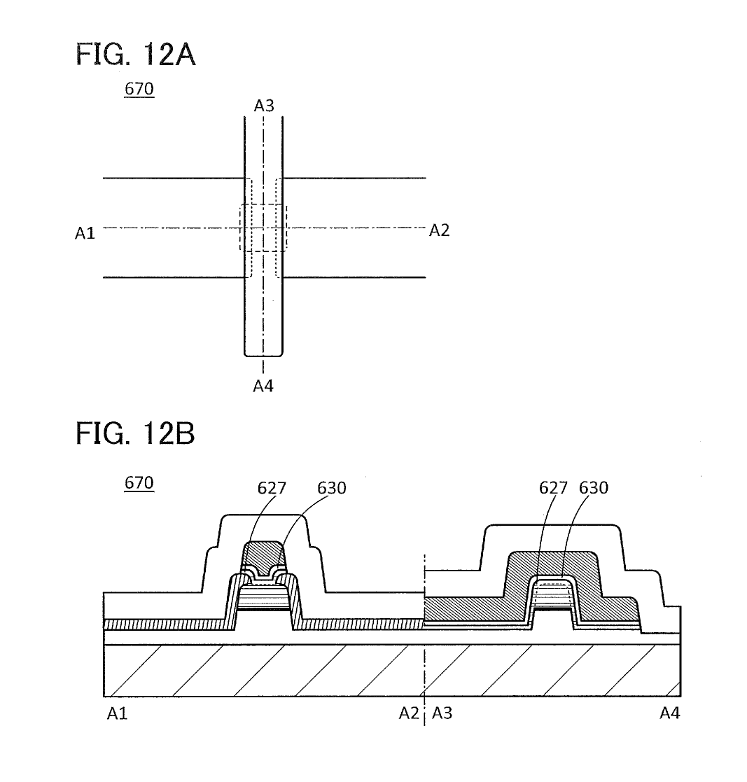

As in a transistor 670 illustrated in FIGS. 12A and 12B, a third oxide semiconductor layer 627 may be provided between the insulating layer 630 and the second oxide semiconductor layer 626. The same material as the first oxide semiconductor layer 624 can be used for the third oxide semiconductor layer 627. Since the third oxide semiconductor layer 627 is in contact with the insulating layer 630 which might contain a constituent element (e.g., silicon) that is different from that of an oxide semiconductor, an interface state due to junction of different kinds of materials, entry of an impurity, or the like might be formed at an interface between the third oxide semiconductor layer 627 and the insulating layer 630. For this reason, to stabilize electrical characteristics of the transistor, the channel is preferably formed in the second oxide semiconductor layer 626. Thus, a material whose electron affinity is lower than that of the second oxide semiconductor layer 626 is preferably used for the third oxide semiconductor layer 627.

The structure and method described in this embodiment can be implemented by being combined as appropriate with any of the other structures and methods described in the other embodiments.

### Embodiment 3

In this embodiment, an example of a semiconductor device manufactured using the evaluation method of one embodiment of the present invention is described.

### <Logic Circuit>

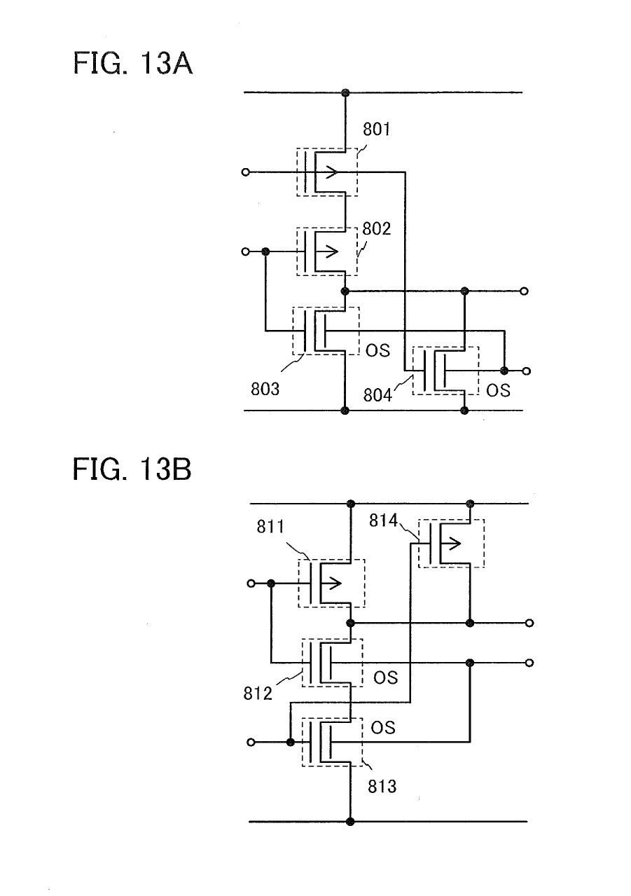

FIG. 13A illustrates an example of a circuit diagram of a NOR circuit, which is a logic circuit, as an example of the semiconductor device described in one embodiment of the present invention. FIG. 13B is a circuit diagram of a NAND circuit.

In the NOR circuit in FIG. 13A, p-channel transistors 801 and 802 are transistors in each of which a channel formation region is formed using a semiconductor material (e.g., silicon) other than an oxide semiconductor, and n-channel transistors 803 and 804 each include an oxide semiconductor and each have a structure similar to that of the transistor described in Embodiment 2.

A transistor including a semiconductor material such as silicon can easily operate at high speed. On the other hand, a transistor including an oxide semiconductor enables charge to be held for a long time owing its characteristics.

To miniaturize the logic circuit, it is preferable that the n-channel transistors 803 and 804 be stacked over the p-channel transistors 801 and 802. For example, the transistors 801 and 802 can be formed using a single crystal silicon substrate, and the transistors 803 and 804 can be formed over the transistors 801 and 802 with an insulating layer provided therebetween.

In the NAND circuit in FIG. 13B, p-channel transistors 811 and 814 are transistors in each of which a channel formation region is formed using a semiconductor material (e.g., silicon) other than an oxide semiconductor, and n-channel transistors 812 and 813 each include an oxide semiconductor layer and each have a structure similar to that of the transistor described in Embodiment 2.

As in the NOR circuit shown in FIG. 13A, to miniaturize the logic circuit, it is preferable that the n-channel transistors 812 and 813 be stacked over the p-channel transistors 811 and 814.

By applying a transistor including an oxide semiconductor for a channel formation region and having extremely small off-state current to the semiconductor device in this embodiment, power consumption of the semiconductor device can be sufficiently reduced.

A semiconductor device which is miniaturized, is highly integrated, and has stable and excellent electrical characteristics by stacking semiconductor elements including different semiconductor materials and a method for manufacturing the semiconductor device can be provided.

In addition, by employing the structure of the transistor including the stacked-layer structure of the oxide semiconductor layers in which a buried channel is formed by using the evaluation method of one embodiment of the present invention, a NOR circuit and a NAND circuit with high reliability and stable characteristics can be provided.

Note that the NOR circuit and the NAND circuit including the transistor described in Embodiment 2 are described as examples in this embodiment; however, the present invention is not particularly limited to the circuits, and an AND circuit, an OR circuit, or the like can be formed using the transistor described in Embodiment 2 or the like. <Memory Device>

In this embodiment, an example of a semiconductor device (memory device) which includes the transistor described in Embodiment 2, which can hold stored data even when not powered, and which has an unlimited number of write cycles is described with reference to drawings.

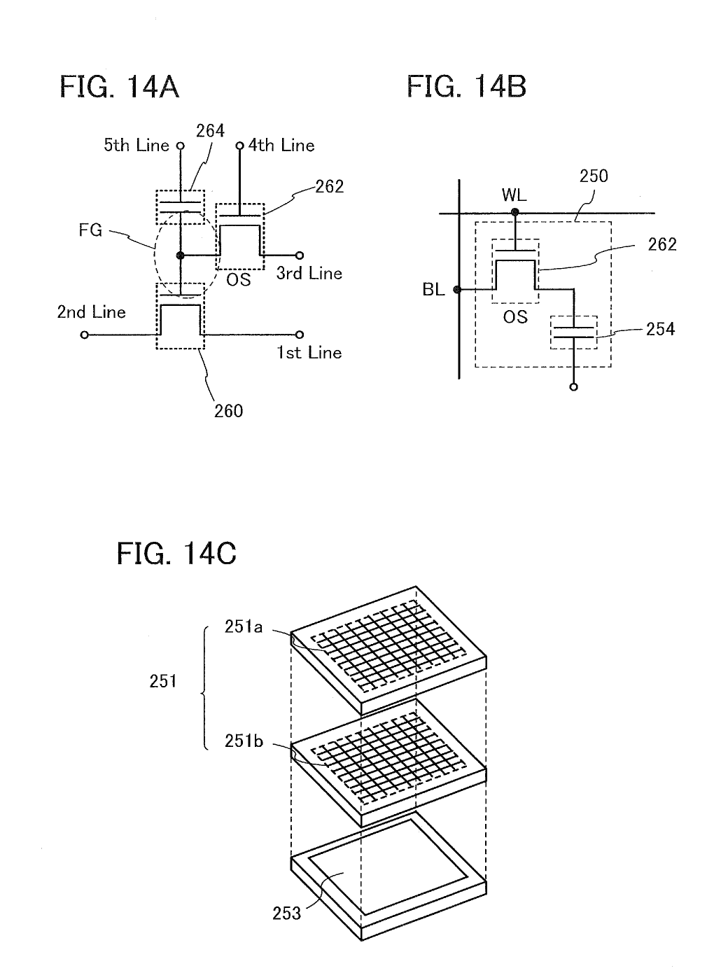

FIG. 14A is a circuit diagram illustrating the semiconductor device of this embodiment.

A transistor including a semiconductor material (e.g., silicon) other than an oxide semiconductor can be applied to a transistor 260 illustrated in FIG. 14A and thus the transistor 260 can easily operate at high speed. Further, a structure similar to that of the transistor described in Embodiment 2 or the like, which includes an oxide semiconductor layer of one embodiment of the present invention, can be applied to a transistor 262 to enable charge to be held for a long e owing to its characteristics.

Although all the transistors are n-channel transistors here, p-channel transistors can be used as the transistors used for the semiconductor device described in this embodiment.

In FIG. 14A, a first wiring (1st Line) is electrically connected to the source electrode layer of the transistor 260, and a second wiring (2nd Line) is electrically connected to a drain electrode layer of the transistor 260. A third wiring (3rd Line) is electrically connected to one of the source electrode layer and the drain electrode layer of the transistor 262, and a fourth wiring (4th Line) is electrically connected to a gate electrode layer of the transistor 262. A gate electrode layer of the transistor 260 and the other of the source electrode layer and the drain electrode layer of the transistor 262 are electrically connected to one electrode of a capacitor 264. A fifth wiring (5th Line) and the other electrode of the capacitor 264 are electrically connected to each other.

The semiconductor device in FIG. 14A can write, hold, and read data as described below, utilizing a characteristic in which the potential of the gate electrode layer of the transistor 260 can be held.

Writing and holding of data are described. First, the potential of the fourth wiring is set to a potential at which the transistor 262 is turned on, so that the transistor 262 is turned on. Thus, the potential of the third wiring is applied to the gate electrode layer of the transistor 260 and the capacitor 264. In other words, a predetermined charge is supplied to the gate electrode layer of the transistor 260 (writing). Here, one of two kinds of charges providing different potential levels (hereinafter referred to as a low-level charge and a high-level charge) is supplied. After that, the potential of the fourth wiring is set to a potential at which the transistor 262 is turned off, so that the transistor 262 is turned off. Thus, the charge given to the gate electrode layer of the transistor 260 is held (bolding).

Since the off-state current of the transistor 262 is extremely low, the charge of the gate electrode layer of the transistor 260 is held for a long time.

Next, reading of data is described. By supplying an appropriate potential (reading potential) to the fifth wiring while supplying a predetermined potential (constant potential) to the first wiring, the potential of the second wiring varies depending on the amount of charge held in the gate electrode layer of the transistor 260. This is because in general, when the transistor 260 is an n-channel transistor, an apparent threshold voltage Vₜₕ_{_{—}}_{H} in the case where a High level charge is given to the gate electrode layer of the transistor 260 is lower than an apparent threshold voltage Vₜₕ_{_{—}}_{L} in the case where a Low level charge is given to the gate electrode layer of the transistor 260. Here, an apparent threshold voltage refers to the potential of the fifth wiring, which is needed to turn on the transistor 260. Thus, the potential of the fifth wiring is set to a potential V₀ which is between Vₜₕ_{_{—}}_{H} and Vₜₕ_{_{—}}_{L}, whereby charge supplied to the gate electrode layer of the transistor 260 can be determined. For example, in the case where High level charge is given in writing, when the potential of the fifth wiring is set to V₀ (>Vₜₕ_{_{—}}_{H}), the transistor 260 is turned on. In the case where Low level charge is given in writing, even when the potential of the fifth wiring is set to V₀ (<Vₜₕ_{_{—}}_{L}), the transistor 260 remains in an off state. Therefore, the stored data can be read by the potential of the second wiring.

Note that in the case where memory cells are arrayed to be used, only data of desired memory cells needs to be read. In the case where such reading is not performed, a potential at which the transistor 260 is turned off regardless of the state of the gate electrode layer, that is, a potential smaller than Vₜₕ_{_{—}}_{V} may be supplied to the fifth wiring. Alternatively, a potential at which the transistor 260 is turned on regardless of the state of the gate electrode layer, that is, a potential larger than Vₜₕ_{_{—}}_{L} may be supplied to the fifth wiring.

FIG. 14B illustrates another example of one embodiment of a structure of a memory device. FIG. 14B illustrates an example of a circuit configuration of a semiconductor device, and FIG. 14C is a schematic diagram illustrating an example of a semiconductor device. First, the semiconductor device illustrated in FIG. 14B is described, and then the semiconductor device illustrated in FIG. 14C will be described.

In the semiconductor device illustrated in FIG. 14B, a bit line BL is electrically connected to the source electrode layer or the drain electrode layer of the transistor 262, a word line WL is electrically connected to the gate electrode layer of the transistor 262, and the source electrode layer or the drain electrode layer of the transistor 262 is electrically connected to a first terminal of a capacitor 254.

Here, the transistor 262 including an oxide semiconductor has extremely low off-state current. For that reason, a potential of the first terminal of the capacitor 254 (or a charge accumulated in the capacitor 254) can be held for an extremely long time by turning off the transistor 262.

Next, writing and holding of data in the semiconductor device (a memory cell 250) illustrated in FIG. 14B will be described.

First, the potential of the word line WL is set to a potential at which the transistor 262 is turned on, so that the transistor 262 is turned on. Accordingly, the potential of the bit line BL is supplied to the first terminal of the capacitor 254 (writing). After that, the potential of the word line WL is set to a potential at which the transistor 262 is turned off, so that the transistor 262 is turned off. Thus, the potential of the first terminal of the capacitor 254 is held (holding).

Because the off-state current of the transistor 262 is extremely small, the potential of the first terminal of the capacitor 254 (or the charge accumulated in the capacitor) can be held for a long time.

Secondly, reading of data will be described. When the transistor 262 is turned on, the bit line BL which is in a floating state and the capacitor 254 are electrically connected to each other, and the charge is redistributed between the bit line BL and the capacitor 254. As a result, the potential of the bit line BL is changed. The amount of change in potential of the bit line EL varies depending on the potential of the first terminal of the capacitor 254 (or the charge accumulated in the capacitor 254).

For example, the potential of the bit line EL after charge redistribution is (C_{B}×V_{B0}+C×V)/(C_{B}+C), where V is the potential of the first terminal of the capacitor 254, C is the capacitance of the capacitor 254, C_{B} is the capacitance of the bit line EL (hereinafter also referred to as bit line capacitance), and V_{B0} is the potential of the bit line BL before the charge redistribution. Therefore, it can be found that assuming that the memory cell 250 is in either of two states in which the potentials of the first terminal of the capacitor 254 are V₁ and V₀ (V₁>V₀), the potential of the bit line BL in the case of holding the potential V₁ (=(C_{B}×V_{B0}+C×V₁)/(C_{B}+C)) is higher than the potential of the bit line BL in the ease of holding the potential V₀ (=(C_{B}×V_{B0}+C×V₀)/(C_{B}+C)).

Then, by comparing the potential of the bit line BL with a predetermined potential, data can be read.

As described above, the semiconductor device illustrated in FIG. 14B can hold charge that is accumulated in the capacitor 254 for a long time because the amount of the off-state current of the transistor 262 is extremely small. In other words, power consumption can be adequately reduced because refresh operation becomes unnecessary or the frequency of refresh operation can be extremely low. Moreover, stored data can be stored for a long time even when power is not supplied.

Next, the semiconductor device illustrated FIG. 14C is described.

The semiconductor device illustrated in FIG. 14C includes a memory cell array 251 (memory cell arrays 251a and 251b) including a plurality of memory cells 250 illustrated in FIG. 14B as memory circuits in the upper portion, and a peripheral circuit 253 in the lower portion which is necessary for operating the memory cell array 251 (the memory cell arrays 251a and 251b). Note that the peripheral circuit 253 is electrically connected to the memory cell array 251.

In the structure illustrated in FIG. 14C, the peripheral circuit 253 can be provided under the memory cell array 251 (the memory cell arrays 251a and 251b). Thus, the size of the semiconductor device can be reduced.

It is preferable that a semiconductor material of a transistor provided in the peripheral circuit 253 be different from that of the transistor 262. For example, silicon, germanium, silicon germanium, silicon carbide, gallium arsenide, or the like can be used, and a single crystal semiconductor is preferably used. Alternatively, an organic semiconductor material or the like may be used. A transistor including such a semiconductor material can operate at sufficiently high speed. Therefore, the transistor can favorably realize a variety of circuits (e.g., a logic circuit or a driver circuit) which needs to operate at high speed.

Note that FIG. 14C illustrates, as an example, the semiconductor device in which two memory cell arrays 251 (the memory cell arrays 251a and 251b) are stacked; however, the number of memory cell arrays which are stacked is not limited thereto. Three or more memory cells arrays may be stacked.

When a transistor in which a buried channel can be formed by application of the evaluation method of one embodiment of the present invention is used as the transistor 262, stored data can be held for a long time. In other words, power consumption can be sufficiently reduced because a semiconductor device in which refresh operation is unnecessary or the frequency of refresh operation is extremely low can be provided.

The structures and methods described in this embodiment can be combined as appropriate with any of the structures and methods described in the other embodiments.

### Embodiment 4

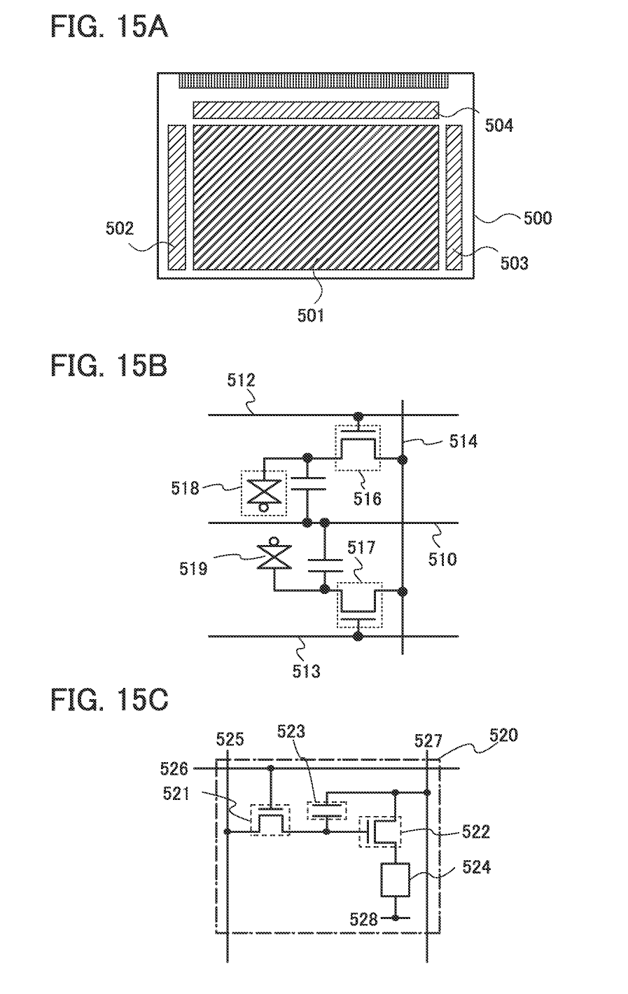

In this embodiment, a structure of a display panel of one embodiment of the present invention is described with reference to FIGS. 15A to 15C.

FIG. 15A is a top view of the display panel of one embodiment of the present invention. FIG. 15B is a circuit diagram illustrating a pixel circuit that can be used in the case where a liquid crystal element is used in a pixel in the display panel of one embodiment of the present invention. FIG. 15C is a circuit diagram illustrating a pixel circuit that can be used in the case where an organic EL element is used in a pixel in the display panel of one embodiment of the present invention.

The transistor in the pixel portion can have the structure described in Embodiment 2 or the like. The transistor can easily be an n-channel transistor, and thus, part of a driver circuit that can be formed using an n-channel transistor in the driver circuit is formed over the same substrate as the transistor of the pixel portion. With the use of the transistor of one embodiment of the present invention for the pixel portion or the driver circuit in this manner, a highly reliable display device can be provided.

FIG. 15A is a block diagram illustrating an example of an active matrix display device. A pixel portion 501, a first scan line driver circuit 502, a second scan line driver circuit 503, and a signal line driver circuit 504 are formed over a substrate 500 of the display device. In the pixel portion 501, a plurality of signal lines extended from the signal line driver circuit 504 are arranged and a plurality of scan lines extended from the first scan line driver circuit 502 and the second scan line driver circuit 503 are arranged. Note that pixels which include display elements are arranged in a matrix in regions where the scan lines and the signal lines are crossed. The substrate 500 of the display device is connected to a timing control circuit (also referred to as a controller or a controller IC) through a connection portion such as a flexible printed circuit (FPC).

In FIG. 15A, the first scan line driver circuit 502, the second scan line driver circuit 503, and the signal line driver circuit 504 are formed over the substrate 500 where the pixel portion 501 is formed. Accordingly, the number of components that are provided outside, such as a driver circuit, can be reduced, so that a reduction in cost can be achieved. Further, if the driver circuit is provided outside the substrate 500, wirings would need to be extended and the number of connections of wirings would be increased, but by providing the driver circuit over the substrate 500, the number of connections of the wirings can be reduced. Consequently, an improvement in reliability or yield can be achieved.

### <Liquid Crystal Panel>

FIG. 15B illustrates an example of a circuit configuration of a pixel. Here, a circuit of a pixel that can be used in a VA liquid crystal display panel is illustrated.

This pixel circuit can be applied to a structure in which one pixel includes a plurality of pixel electrode layers. The pixel electrode layers are connected to different transistors, and the transistors can be driven with different gate signals. Accordingly, signals applied to individual pixel electrode layers in a multi-domain pixel can be controlled independently.

A gate wiring 512 of a transistor 516 and a gate wiring 513 of a transistor 517 are separated so that different gate signals can be supplied thereto. In contrast, a source or drain electrode layer 514 functioning as a data line is shared by the transistors 516 and 517. Any of the transistors described in Embodiment 2 can be used as appropriate as each of the transistors 516 and 517. Thus, the liquid crystal display panel can have high reliability.

The shapes of a first pixel electrode layer electrically connected to the transistor 516 and a second pixel electrode layer electrically connected to the transistor 517 are described. The first pixel electrode layer and the second pixel electrode layer are separated by a slit. The first pixel electrode layer has a V shape and the second pixel electrode layer is provided so as to surround the first pixel electrode.

A gate electrode layer of the transistor 516 is connected to the gate wiring 512, and a gate electrode layer of the transistor 517 is connected to the gate wiring 513. When different gate signals are supplied to the gate wiring 512 and the gate wiring 513, operation timings of the transistor 516 and the transistor 517 can be varied. As a result, alignment of liquid crystals can be controlled.

Furthermore, a storage capacitor may be formed using a capacitor wiring 510, a gate insulating layer functioning as a dielectric, and a capacitor electrode electrically connected to the first pixel electrode layer or the second pixel electrode layer.

The multi-domain pixel includes a first liquid crystal element 518 and a second liquid crystal element 519. The first liquid crystal element 518 includes the first pixel electrode layer, a counter electrode layer, and a liquid crystal layer therebetween. The second liquid crystal element 519 includes the second pixel electrode layer, a counter electrode layer, and a liquid crystal layer therebetween.

Note that a pixel circuit of one embodiment of the present invention is not limited to that shown in FIG. 15B. For example, a switch, a resistor, a capacitor, a transistor, a sensor, a logic circuit, or the like may be added to the pixel shown in FIG. 15B.

### <Organic EL Panel>

FIG. 15C illustrates another example of a circuit configuration of a pixel. Here, a pixel configuration of a display panel including an organic EL element is illustrated.

In an organic EL clement, by application of voltage to a light-emitting clement, electrons are injected from one of a pair of electrodes included in the organic EL element and holes are injected from the other of the pair of electrodes, into a layer containing a light-emitting organic compound; thus, current flows. The electrons and holes are recombined, and thus, the light-emitting organic compound is excited. The light-emitting organic compound returns to a ground state from the excited state, thereby emitting light. Owing to such a mechanism, this light-emitting element is referred to as a current-excitation light-emitting element.

FIG. 15C illustrates an example of a pixel circuit applicable to an organic EL panel. Here, one pixel includes two n-channel transistors. Note that the oxide semiconductor layer can be used for a channel formation region of an n-channel transistor. Further, digital time grayscale driving can be employed for the pixel circuit.

The configuration of the applicable pixel circuit and operation of a pixel employing digital time grayscale driving is described.

A pixel 520 includes a switching transistor 521, a driver transistor 522, a light-emitting element 524, and a capacitor 523. A gate electrode layer of the switching transistor 521 is connected to a scan line 526, a first electrode (one of a source electrode layer and a drain electrode layer) of the switching transistor 521 is connected to a signal line 525, and a second electrode (the other of the source electrode layer and the drain electrode layer) of the switching transistor 521 is connected to a gate electrode layer of the driver transistor 522. The gate electrode layer of the driver transistor 522 is connected to a power supply line 527 through the capacitor 523, a first electrode of the driver transistor 522 is connected to the power supply line 527, and a second electrode of the driver transistor 522 is connected to a first electrode (a pixel electrode) of the light-emitting element 524. A second electrode of the light-emitting element 524 corresponds to a common electrode 528. The common electrode 528 is electrically connected to a common potential line provided over the same substrate.

As each of the switching transistor 521 and the driver transistor 522, the transistor of one embodiment of the present invention can be used as appropriate. In this manner, a highly reliable organic EL panel can be provided.

The potential of the second electrode (the common electrode 528) of the light-emitting element 524 is set to be a low power supply potential. Note that the low power supply potential is lower than a high power supply potential supplied to the power supply line 527. For example, the low power supply potential can be GND, 0 V, or the like. The high power supply potential and the low power supply potential are set to be higher than or equal to the forward threshold voltage of the light-emitting element 524, and the difference between the potentials is applied to the light-emitting element 524, whereby current is supplied to the light-emitting element 524 leading to light emission. The forward voltage of the light-emitting element 524 refers to a voltage at which a desired luminance is obtained, and includes at least forward threshold voltage.

Note that gate capacitance of the driver transistor 522 can be used as a substitute for the capacitor 523, so that the capacitor 523 can be omitted. The gate capacitance of the driver transistor 522 may be formed between the channel formation region and the gate electrode layer.

Next, a signal input to the driver transistor 522 is described. In the case of a voltage-input voltage driving method, a video signal for sufficiently turning on or off the driver transistor 522 is input to the driver transistor 522. In order for the driver transistor 522 to operate in a linear region, voltage higher than the voltage of the power supply line 527 is applied to the gate electrode of the driver transistor 522. Note that voltage higher than or equal to voltage which is the sum of power supply line voltage and the threshold voltage Vₜₕ of the driver transistor 522 is applied to the signal line 525.

In the case of performing analog grayscale driving, a voltage higher than or equal to a voltage which is the sum of the forward voltage of the light-emitting element 524 and the threshold voltage Vₜₕ of the driver transistor 522 is applied to the gate electrode layer of the driver transistor 522. A video signal by which the driver transistor 522 is operated in a saturation region is input, so that current is supplied to the light-emitting element 524. In order for the driver transistor 522 to operate in a saturation region, the potential of the power supply line 527 is set higher than the gate potential of the driver transistor 522. When an analog video signal is used, it is possible to supply current to the light-emitting element 524 in accordance with the video signal and perform analog grayscale driving.

Note that a configuration of a pixel circuit is not limited to that shown in FIG. 15C. For example, a switch, a resistor, a capacitor, a sensor, a transistor, a logic circuit, or the like may be added to the pixel circuit shown in FIG. 15C.

### <Electronic Appliance>

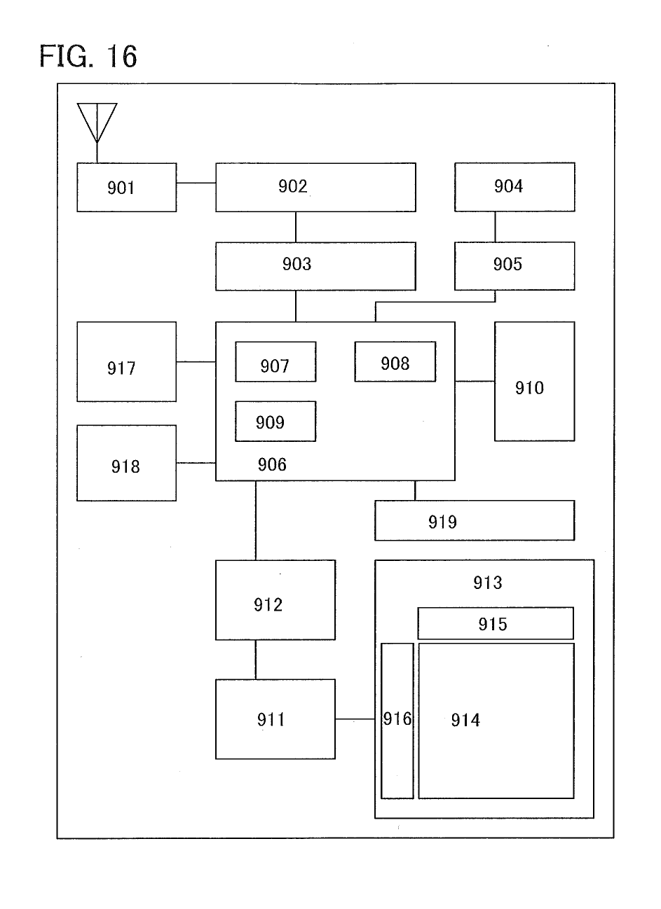

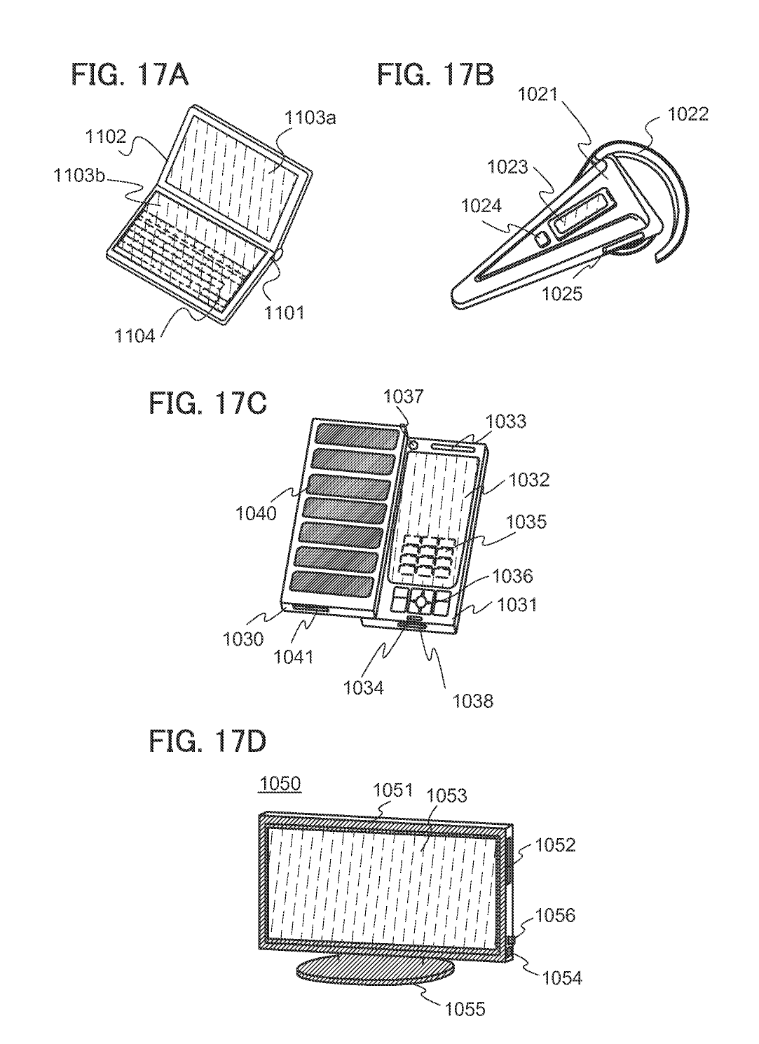

FIG. 16 is a block diagram of an electronic appliance including a semiconductor device to which a transistor formed using the evaluation method of one embodiment of the present invention is applied. FIGS. 17A to 17D are each an external view of an electronic appliance including the semiconductor device to which the transistor formed using the evaluation method of one embodiment of the present invention is applied.

An electronic appliance illustrated in FIG. 16 includes an RF circuit 901, an analog baseband circuit 902, a digital baseband circuit 903, a battery 904, a power supply circuit 905, an application processor 906, a flash memory 910, a display controller 911, a memory circuit 912, a display 913, a touch sensor 919, an audio circuit 917, a keyboard 918, and the like. The application processor 906 includes a CPU 907, a DSP 908, and an interface (IF) 909. Moreover, the memory circuit 912 can include an SRAM or a DRAM.

When the transistor of one embodiment of the present invention is applied to the memory circuit 912, the CPU 907, the DSP 908, or the like, a reliable electronic appliance can be provided.

Note that in the case where the off-state leakage current of the transistor is extremely small, the memory circuit 912 can store data for a long time and can have sufficiently reduced power consumption. Moreover, the CPU 907 or the DSP 908 can store the state before power gating in a register or the like during a period in which the power gating is performed.

Furthermore, the display 913 includes a display portion 914, a source driver 915, and a gate driver 916. The display portion 914 includes a plurality of pixels arranged in a matrix. The pixel includes a pixel circuit, and the pixel circuit is electrically connected to the gate driver 916.

The transistor of one embodiment of the present invention can be used as appropriate in the pixel circuit or the gate driver 916. Accordingly, a highly reliable display can be provided.

Examples of electronic appliances are a television set (also referred to as a television or a television receive monitor of a computer or the like, a camera such as a digital camera or a digital video camera, a digital photo frame, a mobile phone handset (also referred to as a mobile phone or a mobile phone device), a portable game machine, a portable information terminal, an audio reproducing device, a large-sized game machine such as a pachinko machine, and the like.

FIG. 17A illustrates a portable information terminal, which includes a main body 1101, a housing 1102, a display portion 1103a, a display portion 1103b, and the like. The display portion 1103b includes a touch panel. By touching a keyboard button 1104 displayed on the display portion 1103b, screen operation can be carried out, and text can be input. Needless to say, the display portion 1103a may function as a touch panel. A liquid crystal panel or an organic light-emitting panel is fabricated using the transistor of one embodiment of the present invention as a switching element and applied to the display portion 1103a or 1103b, whereby a highly reliable portable information terminal can be provided.

The portable information terminal illustrated in FIG. 17A can have a function of displaying a variety of kinds of data (e.g., a still image, a moving image, and a text image), a function of displaying a calendar, a date, the time, or the like on the display portion, a function of operating or editing data displayed on the display portion, a function of controlling processing by a variety of kinds of software (programs), and the like. Further, an external connection terminal (an earphone terminal, a USB terminal, or the like), a recording medium insertion portion, or the like may be provided on the back surface or the side surface of the housing.

The portable information terminal illustrated in FIG. 17A may transmit and receive data wirelessly. Through wireless communication, desired book data or the like can be purchased and downloaded from an electronic book server.

FIG. 17B illustrates a portable music player including, in a main body 1021, a display portion 1023, a fixing portion 1022 with which the portable music player can be worn on the ear, a speaker, an operation button 1024, an external memory slot 1025, and the like. A liquid crystal panel or an organic light-emitting panel is fabricated using the transistor of one embodiment of the present invention as a switching element and applied to the display portion 1023, whereby a highly reliable portable music player can be provided.

Furthermore, when the portable music player illustrated in FIG. 17B has an antenna, a microphone function, or a wireless communication function and is used with a mobile phone, a user can talk on the phone wirelessly in a hands-free way while driving a car or the like.

FIG. 17C illustrates a mobile phone that includes two housings, a housing 1030 and a housing 1031. The housing 1031 includes a display panel 1032, a speaker 1033, a microphone 1034, a pointing device 1036, a camera lens 1037, an external connection terminal 1038, and the like. The housing 1030 is provided with a solar cell 1040 for charging the mobile phone, an external memory slot 1041, and the like. In addition, an antenna is incorporated in the housing 1031. The transistor of one embodiment of the present invention is applied to the display panel 1032, whereby a highly reliable mobile phone can be provided.

Furthermore, the display panel 1032 includes a touch panel. A plurality of operation keys 1035 that are displayed as images are indicated by dotted lines in FIG. 17C. Note that a boosting circuit by which a voltage output from the solar cell 1040 is increased so as to be sufficiently high for each circuit is also included.

In the display panel 1032, the direction of display is changed as appropriate depending on the application mode. Furthermore, the mobile phone is provided with the camera lens 1037 on the same surface as the display panel 1032, and thus it can be used as a video phone. The speaker 1033 and the microphone 1034 can be used for videophone calls, recording, and playing sound, and the like as well as voice calls. Moreover, the housings 1030 and 1031 in a state where they are developed as illustrated in FIG. 17C can shift, by sliding, to a state where one is lapped over the other. Therefore, the size of the mobile phone can be reduced, which makes the mobile phone suitable for being carried around.

The external connection terminal 1038 can be connected to an AC adaptor and a variety of cables such as a USB cable, whereby charging and data communication with a personal computer or the like are possible. Further, by inserting a recording medium into the external memory slot 1041, a larger amount of data can be stored and moved.

In addition, in addition to the above functions, an infrared communication function, a television reception function, or the like may be provided.

FIG. 17D illustrates an example of a television set. In a television set 1050, a display portion 1053 is incorporated in a housing 1051. Images can be displayed on the display portion 1053. Moreover, a CPU is incorporated in a stand 1055 for supporting the housing 1051. The transistor of one embodiment of the present invention is applied to the display portion 1053 and the CPU, whereby the television set 1050 can be highly reliable.

The television set 1050 can be operated with an operation switch of the housing 1051 or a separate remote controller. Furthermore, the remote controller may be provided with a display portion for displaying data output from the remote controller.

Note that the television set 1050 is provided with a receiver, a modem, and the like. With the use of the receiver, the television set 1050 can receive general TV broadcasts. Moreover, when the television set 1050 is connected to a communication network with or without wires via the modem, one-way (from a sender to a receiver) or two-way (between a sender and a receiver or between receivers) information communication can be performed.

Moreover, the television set 1050 is provided with an external connection terminal 1054, a storage medium recording and reproducing portion 1052, and an external memory slot. The external connection terminal 1054 can be connected to various types of cables such as a USB cable, whereby data communication with a personal computer or the like is possible. A disk storage medium is inserted into the storage medium recording and reproducing portion 1052, and reading data stored in the storage medium and writing data to the storage medium can be performed. In addition, an image, a video, or the like stored as data in an external memory 1056 inserted into the external memory slot can be displayed on the display portion 1053.

In addition, in the case where the offstate leakage current of the transistor of one embodiment of the present invention is extremely small, when the transistor is applied to the external memory 1056 or the CPU, the television set 1050 can have high reliability and sufficiently reduced power consumption.

The structures, the methods, and the like described in this embodiment can be combined as appropriate with any of the structures, the methods, and the like described in the other embodiments.

This application is based on Japanese Patent Application serial no. 2013-219017 filed with Japan Patent Office on Oct. 22, 2013, the entire contents of which are hereby incorporated by reference.

What is claimed is:

1. A method for evaluating a semiconductor device comprising a transistor,
wherein the method comprises the step of:
obtaining a CV characteristic of the transistor; and
determining that a semiconductor layer of the transistor comprises a stacked-layer structure when the CV characteristic has a capacitance value higher than a saturated value.

2. The method for evaluating a semiconductor device according to claim 1,
wherein the semiconductor layer comprises an oxide semiconductor.

3. The method for evaluating a semiconductor device according to claim 1,
wherein the saturated value is a capacitance value of the transistor which is in an accumulation state.

4. The method for evaluating a semiconductor device according to claim 1,
wherein the transistor comprises a gate electrode, a source electrode, and a drain electrode, and
wherein the CV characteristic is obtained by measuring a relationship between a potential of the gate electrode and a capacitance between the gate electrode and each of the source electrode and the drain electrode.

5. The method for evaluating a semiconductor device according to claim 1,
wherein the transistor comprises a gate electrode, and
wherein the CV characteristic is obtained by applying DC voltage and AC voltage to the gate electrode.

6. The method for evaluating a semiconductor device according to claim 1,
wherein the transistor comprises a gate electrode,
wherein the CV characteristic is obtained by applying DC voltage and AC voltage to the gate electrode, and
wherein a frequency of the AC voltage is higher than or equal to 0.3 kHz and lower than or equal to 1 kHz.

7. The method for evaluating a semiconductor device according to claim 1,
wherein the CV characteristic is increased stepwise when the semiconductor layer comprises the stacked-layer structure.

8. The method for evaluating a semiconductor device according to claim 1,
wherein a channel is formed in an one layer of the stacked-layer structure when the semiconductor layer comprises the stacked-layer structure and a capacitance value of the transistor is lower than the saturated value.

9. A method for evaluating a semiconductor device comprising a first transistor and a second transistor,
wherein compositions or thicknesses of semiconductor layers of the first transistor and the second transistor are different from each other, and
wherein the method comprises the step of:
obtaining a first CV characteristic of the first transistor;
obtaining a second CV characteristic of the second transistor; and
evaluating an optimal composition or thickness of the semiconductor layers of the first transistor and the second transistor by measuring a first embedment breakdown voltage of the first CV characteristic and a second embedment breakdown voltage of the second CV characteristic.

10. The method for evaluating a semiconductor device according to claim 9,
wherein the semiconductor layers of the first transistor and the second transistor comprise an oxide semiconductor.

11. The method for evaluating a semiconductor device according to claim 9,
wherein a capacitance value of the first transistor is higher than a saturated value of the first CV characteristic when a potential of a gate electrode of the first transistor is higher than the first embedment breakdown voltage, and
wherein a capacitance value of the second transistor is higher than a saturated value of the second CV characteristic when a potential of a gate electrode of the second transistor is higher than the second embedment breakdown voltage.

12. The method for evaluating a semiconductor device according to claim 9,
wherein each of the first transistor and the second transistor comprises a gate electrode, a source electrode, and a drain electrode, and
wherein each of the first CV characteristic and the second CV characteristic is obtained by measuring a relationship between a potential of the gate electrode and a capacitance between the gate electrode and each of the source electrode and the drain electrode.

13. The method for evaluating a semiconductor device according to claim 9,
wherein each of the first transistor and the second transistor comprises a gate electrode, and
wherein each of the first CV characteristic and the second CV characteristic is obtained by applying DC voltage and AC voltage to the gate electrode.

14. The method for evaluating a semiconductor device according to claim 9,
wherein each of the first transistor and the second transistor comprises a gate electrode,
wherein each of the first CV characteristic and the second CV characteristic is obtained by applying DC voltage and AC voltage to the gate electrode, and
wherein a frequency of the AC voltage is higher than or equal to 0.3 kHz and lower than or equal to 1 kHz.

15. A method for evaluating a semiconductor device comprising a first transistor and a second transistor,
wherein thicknesses of gate insulating layers of the first transistor and the second transistor are different from each other, and
wherein the method comprises the step of:
obtaining a first CV characteristic of the first transistor;
obtaining a second CV characteristic of the second transistor; and
evaluating an optimal thickness of the gate insulating layers of the first transistor and the second transistor by measuring a first embedment breakdown voltage of the first CV characteristic and a second embedment breakdown voltage of the second CV characteristic.

16. The method for evaluating a semiconductor device according to claim 15,
wherein semiconductor layers of the first transistor and the second transistor comprise an oxide semiconductor.

17. The method for evaluating a semiconductor device according to claim 15,
wherein a capacitance value of the first transistor is higher than a saturated value of the first CV characteristic when a potential of a gate electrode of the first transistor is higher than the first embedment breakdown voltage, and
wherein a capacitance value of the second transistor is higher than a saturated value of the second CV characteristic when a potential of a gate electrode of the second transistor is higher than the second embedment breakdown voltage.

18. The method for evaluating a semiconductor device according to claim 15,
wherein each of the first transistor and the second transistor comprises a gate electrode, a source electrode, and a drain electrode, and
wherein each of the first CV characteristic and the second CV characteristic is obtained by measuring a relationship between a potential of the gate electrode and a capacitance between the gate electrode and each of the source electrode and the drain electrode.

19. The method for evaluating a semiconductor device according to claim 15,
wherein each of the first transistor and the second transistor comprises a gate electrode, and
wherein each of the first CV characteristic and the second CV characteristic is obtained by applying DC voltage and AC voltage to the gate electrode.

20. The method for evaluating a semiconductor device according to claim 15,
wherein each of the first transistor and the second transistor comprises a gate electrode,
wherein each of the first CV characteristic and the second CV characteristic is obtained by applying DC voltage and AC voltage to the gate electrode, and
wherein a frequency of the AC voltage is higher than or equal to 0.3 kHz and lower than or equal to 1 kHz.
